(19) United States
(12) Patent Application Publication
(10) Pub. No.: US 2026/0182059 A1
(43) Pub. Date: Jun. 25, 2026

(54) IMAGE SENSOR

(71) Applicant: Samsung Electronics Co., Ltd., Suwon-si (KR)

(72) Inventor: Hyuk Hur, Suwon-si (KR)

(21) Appl. No.: 19/275,396

(22) Filed: Jul. 21, 2025

(30) Foreign Application Priority Data
Dec. 23, 2024 (KR) 10-2024-0194677

(51) Int. Cl. H10F 39/00

(52) U.S. Cl. CPC H10F 39/8057; H10F 39/8053; H10F 39/8063

(57) ABSTRACT

An embodiment relates to an image sensor includes: a sensor substrate with first pixels sensing light of a first wavelength and second pixels sensing light of a second wavelength; first and second color filters corresponding to respective pixels; a transparent spacer on the color filters; at least one color separation lens array on the spacer that changes phases of light to concentrate first wavelength light onto first pixels and second wavelength light onto second pixels; and an anti-reflective layer positioned at least one of: on the lens array's upper surface, between the spacer and color filters, or between the color filters and sensor substrate. The anti-reflective layer features plurality of patterns with quasi-periodicity.

### CROSS-REFERENCE TO RELATED APPLICATION

This application is based on and claims priority under 35 U.S.C. § 119 to Korean Patent Application No. 10-2024-0194677, filed on Dec. 23, 2024, in the Korean Intellectual Property Office, the disclosure of which is incorporated by reference herein in its entirety.

### BACKGROUND

The inventive concept relates to an image sensor, and more particularly, to an image sensor with reduced image artifacts.

Image sensors convert an optical image into an electrical signal. Such image sensors may be classified into a charge-coupled device (CCD) type and a complementary metal oxide semiconductor (CMOS) type. A CMOS-type image sensor is referred to as a CMOS image sensor (CIS). The CIS includes a plurality of pixels that are two-dimensionally arranged. Each pixel includes a photodiode. The photodiode converts incident light into an electrical signal.

### SUMMARY

The inventive concept reduces image artifacts of an image sensor.

In addition, the problems to be solved by the technical idea of the inventive concept are not limited to the problem mentioned above, and other problems could be clearly understood by those of ordinary skill in the art from the description below.

According to an aspect of the present disclosure, an image sensor includes a sensor substrate including a first pixel configured to sense light of a first wavelength and a second pixel configured to sense light of a second wavelength that is different from the first wavelength, a color filter array including a first color filter and a second color filter and disposed on the sensor substrate, wherein the first color filter and the second color filter overlap the first pixel and the second pixel, respectively, a spacer that is transparent and disposed on the first color filter and the second color filter, a first color separation lens array disposed on the spacer and configured to change a phase of the light of the first wavelength such that the light of the first wavelength is concentrated on the first pixel, and change a phase of the light of the second wavelength such that the light of the second wavelength is concentrated on the second pixel, and an anti-reflective layer located at least one of on an upper surface of the first color separation lens array, between the spacer and the color filter array, and between the color filter array and the sensor substrate. The anti-reflective layer has a plurality of patterns that are arranged in a quasi-periodic manner.

According to an aspect of the present disclosure, an image sensor includes a sensor substrate including a pixel configured to sense light, a color filter disposed on the sensor substrate and overlapping the pixel, an optical lens array disposed on the color filter and configured to concentrate the light on the pixel, and an anti-reflective layer located at least one of: on the optical lens array, between the optical lens array and the color filter, and between the color filter and the sensor substrate. The anti-reflective layer has a plurality of patterns that are arranged in a quasi-periodic manner.

According to an aspect of the present disclosure, an image sensor includes a sensor substrate including a first pixel configured to sense light of a first wavelength and a second pixel configured to sense light of a second wavelength that is different from the first wavelength, a spacer that is transparent and disposed on the sensor substrate, a color filter array including a first color filter and a second color filter and disposed between the sensor substrate and the spacer, wherein the first color filter and the second color filter overlap the first pixel and the second pixel, respectively, a first color separation lens array disposed on the spacer, wherein the first color separation lens array includes a plurality of first nanoposts arranged to concentrate incident light on the first pixel and the second pixel, and a first dielectric layer surrounding a side surface of each first nanosheet of the plurality of first nanoposts and including a dielectric material having a refractive index lower than a refractive index of a material of the plurality of first nanoposts, a second color separation lens array disposed on the first color separation lens array, wherein the second color separation lens array includes a plurality of second nanoposts arranged at a horizontal directional position that is different from a horizontal directional position of the plurality of first nanoposts, and a second dielectric layer surrounding a side surface of each second nanopost of the plurality of second nanoposts and including a dielectric material having a refractive index lower than a material of the plurality of second nanoposts, a first etch stopper disposed between the spacer and the first color separation lens array, and an anti-reflective layer located at least one of: on an upper surface of the second color separation lens array, between the spacer and the color filter array, and between the color filter array and the sensor substrate. The anti-reflective layer has a plurality of patterns that are arranged in a quasi-periodic manner.

### BRIEF DESCRIPTION OF THE DRAWINGS

Embodiments of the inventive concept will be more clearly understood from the following detailed description taken in conjunction with the accompanying drawings in which:

FIG. 1 is a schematic exploded perspective view of an image sensor according to embodiments;

FIG. 2 is a block diagram illustrating some components of an image sensor according to embodiments;

FIGS. 3 to 5 illustrate various pixel arrangements of a pixel array of an image sensor according to an embodiment;

FIGS. 6A and 6B are cross-sectional views of partial areas of an image sensor according to an embodiment;

FIG. 7 is a top view illustrating an anti-reflective layer of an image sensor according to an embodiment;

FIGS. 8 and 9 are enlarged views of a region A of FIG. 6A, according to embodiments;

FIG. 10 is a top view illustrating an arrangement of pixels in a pixel array;

FIG. 11 is a top view illustrating a color separation lens array included in an image sensor according to an embodiment;

FIG. 12 is a cross-sectional view of a partial area of an image sensor according to another embodiment;

FIG. 13 is a cross-sectional view of a partial area of an image sensor according to another embodiment;

FIG. 14 is a cross-sectional view of a partial area of an image sensor according to another embodiment;

FIG. 15 is a cross-sectional view of a partial area of an image sensor according to another embodiment;

FIG. 16 is a cross-sectional view of a partial area of an image sensor according to another embodiment;

FIG. 17 is a cross-sectional view of a partial area of an image sensor according to another embodiment;

FIG. 18 is a block diagram of an electronic device including a multi-camera module;

FIG. 19 is a detailed block diagram of a camera module of FIG. 18;

FIG. 20 is a block diagram illustrating an image sensor according to an embodiment;

FIG. 21 is a block diagram schematically illustrating an electronic device including an image sensor according to embodiments; and

FIG. 22 is a block diagram schematically illustrating a camera module of FIG. 21.

### DETAILED DESCRIPTION OF THE EMBODIMENTS

Hereinafter, embodiments are described in detail with reference to the accompanying drawings. Like reference numerals in the drawings denote like elements, and thus their repetitive description is omitted.

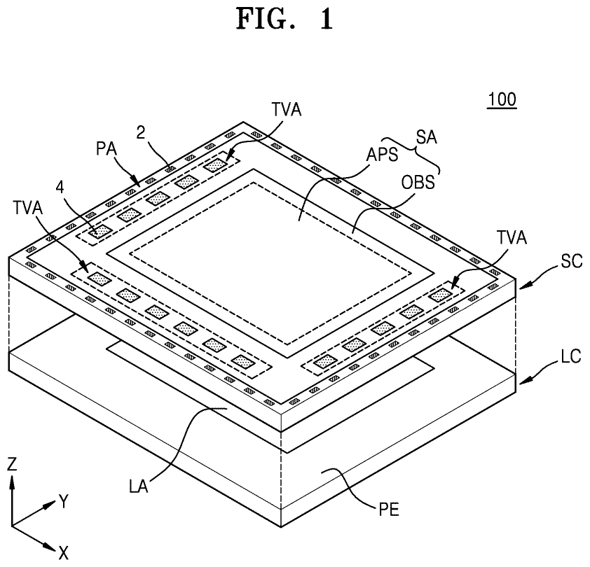

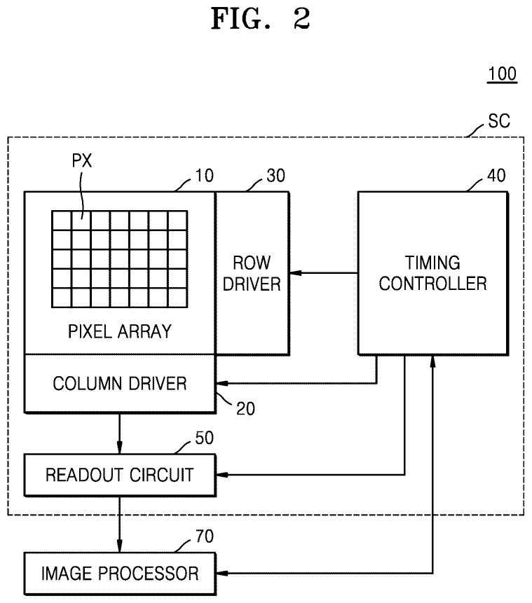

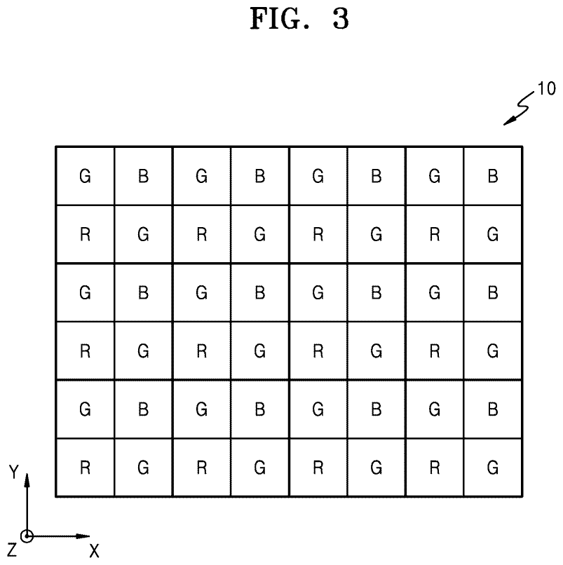

FIG. 1 is a schematic exploded perspective view of an image sensor 100 according to embodiments. FIG. 2 is a block diagram illustrating some components of the image sensor 100 according to embodiments. FIGS. 3 to 5 illustrate various pixel arrangements of a pixel array 10 of the image sensor 100 according to an embodiment.

Referring to FIG. 1, the image sensor 100 may include a first semiconductor chip LC and a second semiconductor chip SC overlapping each other in a vertical direction (the Z direction). The first semiconductor chip LC may be a logic chip, and the second semiconductor chip SC may be a sensor chip.

The first semiconductor chip LC may include a logic area LA including logic devices and a peripheral circuit area PE including peripheral circuits. The logic area LA may be surrounded by the peripheral circuit area PE.

The second semiconductor chip SC may be stacked on the first semiconductor chip LC so as to overlap the first semiconductor chip LC in the vertical direction (the Z direction). The second semiconductor chip SC may include a sensor array area SA, a pad area PA surrounding the sensor array area SA, and a plurality of through via areas TVA between the sensor array area SA and the pad area PA. In the second semiconductor chip SC, the plurality of through via areas TVA and the pad area PA may constitute a peripheral circuit area of the second semiconductor chip SC.

In the second semiconductor chip SC, the sensor array area SA may include an active pixel sensor area APS including an active pixel configured to generate an active signal corresponding to wavelengths of light from the outside and an optical black sensor area OBS including an optical black pixel configured to generate an optical black signal by blocking light from the outside. A dummy pixel sensor may be disposed in an edge portion of the active pixel sensor area APS close to the optical black sensor area OBS.

A plurality of pads 2 may be disposed in the pad area PA of the second semiconductor chip SC. In embodiments, the plurality of pads 2 may exchange an electrical signal with an external device. In some embodiments, the plurality of pads 2 may transfer driving power, such as a power source voltage or a ground voltage supplied from the outside, to circuits in the second semiconductor chip SC.

A plurality of through vias 4 may be disposed in the plurality of through via areas TVA included in the second semiconductor chip SC. Some of the plurality of through vias 4 may be connected to unit pixels in the sensor array area SA via wirings included in the second semiconductor chip SC. Some other through vias 4 may connect wirings included in the first semiconductor chip LC to wirings included in the second semiconductor chip SC. Yet some other through vias 4 may connect wirings included in the first semiconductor chip LC to logic devices in the logic area LA included in the second semiconductor chip SC.

Referring to FIGS. 1 and 2, the image sensor 100 may include the pixel array 10 in the sensor array area SA and circuits configured to control the pixel array 10. In embodiments, the circuits configured to control the pixel array 10 may include a column driver 20, a row driver 30, a timing controller 40, and a readout circuit 50.

The image sensor 100 may operate in response to a control command received from an image processor 70, and convert light transferred from an external object into an electrical signal and output the electrical signal to the image processor 70. The image sensor 100 may be a complementary metal oxide semiconductor (CMOS) image sensor.

The pixel array 10 may include a plurality of unit pixels PX having a two-dimensional array structure arranged in a matrix form along a plurality of row lines and a plurality of column lines. The term “unit pixel” used in the specification may be simply referred to as a pixel.

Each of the plurality of unit pixels PX may include a photodiode. The photodiode may generate charges by receiving light transferred from an object. The image sensor 100 may perform an autofocus function by using a phase difference of pixel signals generated by a plurality of photodiodes included in the plurality of unit pixels PX. Each of the plurality of unit pixels PX may include a pixel circuit configured to generate a pixel signal from charges generated by a photodiode.

In embodiments, the image sensor 100 may perform a global shutter operation. For example, when the image sensor 100 operates the global shutter operation, all of the plurality of unit pixels PX included in the pixel array 10 may be simultaneously exposed to an optical signal provided from the outside such that charges are simultaneously stored in the plurality of unit pixels PX. In embodiments, pixel signals by the charges stored in the plurality of unit pixels PX may be sequentially output for each row.

The column driver 20 may include a correlated double sampler (CDS) or an analog-to-digital converter (ADC). The CDS is connected through column lines to a unit pixel PX included in a row selected using a row select signal supplied from the row driver 30 and may detect a reset voltage and a pixel voltage by performing correlated double sampling. The ADC may convert the reset voltage and the pixel voltage detected by the CDS into a digital signal and transmit the digital signal to the readout circuit 50.

The readout circuit 50 may include a latch or buffer circuit capable of temporarily storing a digital signal received from the column driver 20, or an amplification circuit (i.e., an amplifier circuit) that generates image data by amplifying the temporarily stored digital signal. Operation timings of the column driver 20, the row driver 30, and the readout circuit 50 may be determined by the timing controller 40, and the timing controller 40 may operate in response to a control command transmitted from the image processor 70.

The image processor 70 may perform signal processing on the image data output from the readout circuit 50 and output the signal-processed image data to a display device or store the signal-processed image data in a storage device, such as a memory. When the image sensor 100 is mounted on an autonomous vehicle, the image processor 70 may perform signal processing on image data and transmit the signal-processed image data to a main controller configured to control the autonomous vehicle.

Referring to FIGS. 3 to 5, the pixel array 10 may include a plurality of pixels configured to sense light of different wavelengths. An arrangement of pixels may be implemented in various ways. For example, FIGS. 3 to 5 illustrate various pixel arrangements of the pixel array 10 of the image sensor 100.

First, FIG. 3 illustrates a Bayer pattern generally employed in the image sensor 100. Referring to FIG. 3, one unit pattern includes four quadrant regions, e.g., first to fourth quadrant regions, and the first to fourth quadrant regions may be a blue pixel B, a green pixel G, a red pixel R, and a green pixel G, respectively. Such a unit pattern is two-dimensionally and repeatedly arranged in a first direction (the X direction) and a second direction (the Y direction).

For example, in a unit pattern of a 2×2 array form, two green pixels G are arranged in one diagonal direction, and one blue pixel B and one red pixel R are arranged in the other diagonal direction. According to the general pixel arrangement, a first row in which a plurality of green pixels G and a plurality of blue pixels B are alternately arranged in the first direction (the X direction) and a second row in which a plurality of red pixels R and a plurality of green pixels G are alternately arranged in the first direction (the X direction) are repeatedly arranged in the second direction (the Y direction).

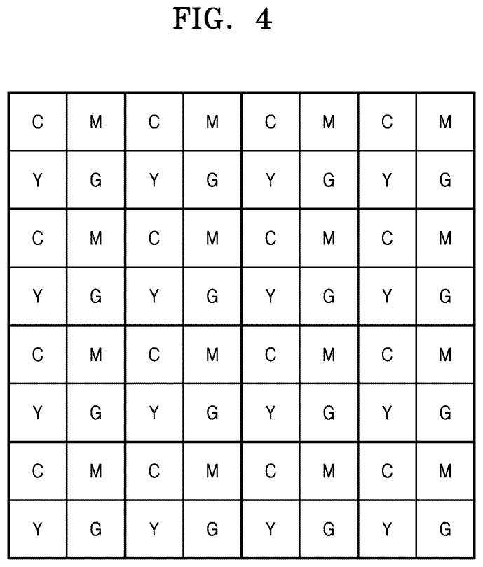

Besides the Bayer pattern, various arrangements such as a tetra arrangement and a nona arrangement may be applied to the pixel array 10. For example, referring to FIG. 4, a CYGM arrangement in which one unit pattern consists of a magenta pixel M, a cyan pixel C, a yellow pixel Y, and a green pixel G is also available.

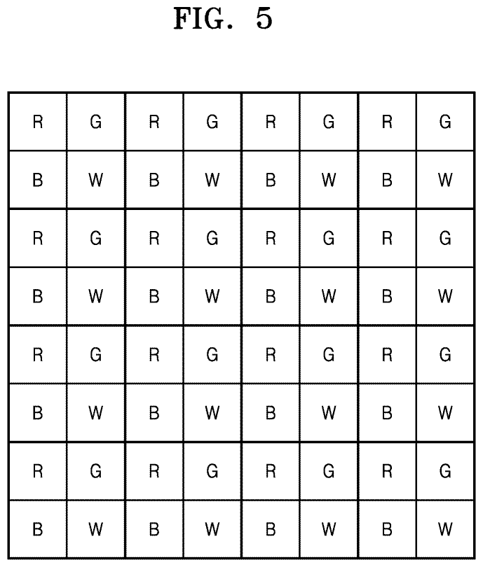

Referring to FIG. 5, an RGBW arrangement in which one unit pattern consists of a green pixel G, a red pixel R, a blue pixel B, and a white pixel W is also available.

Although not shown, a unit pattern may have a 3×2 array form. The plurality of pixels in the pixel array 10 may be arranged in various ways according to the color characteristics of the image sensor 100. Hereinafter, although it is described as an example that the pixel array 10 of the image sensor 100 has the Bayer pattern, the operation principle of the pixel array 10 may also be applied to pixel arrangements other than the Bayer pattern.

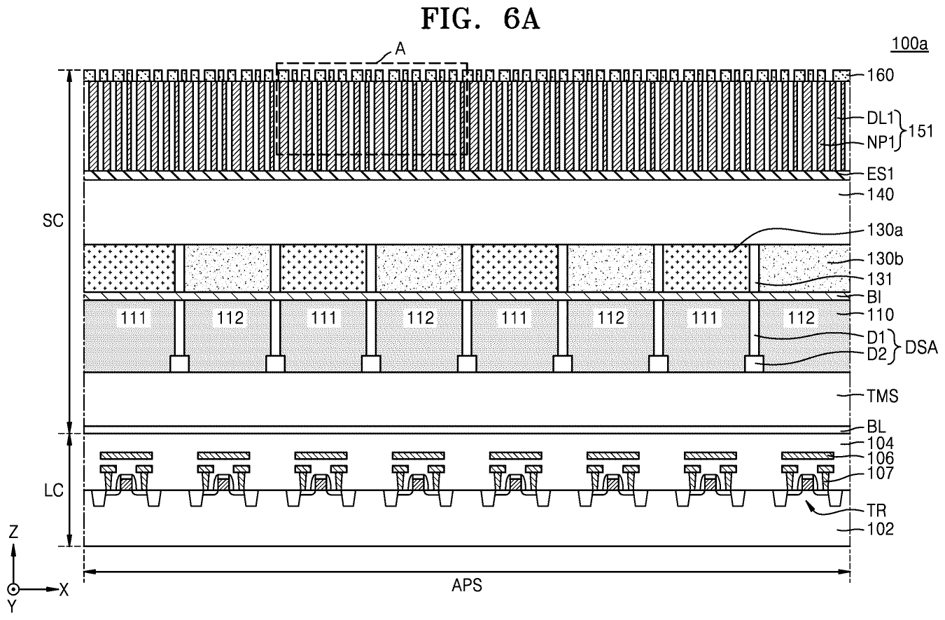

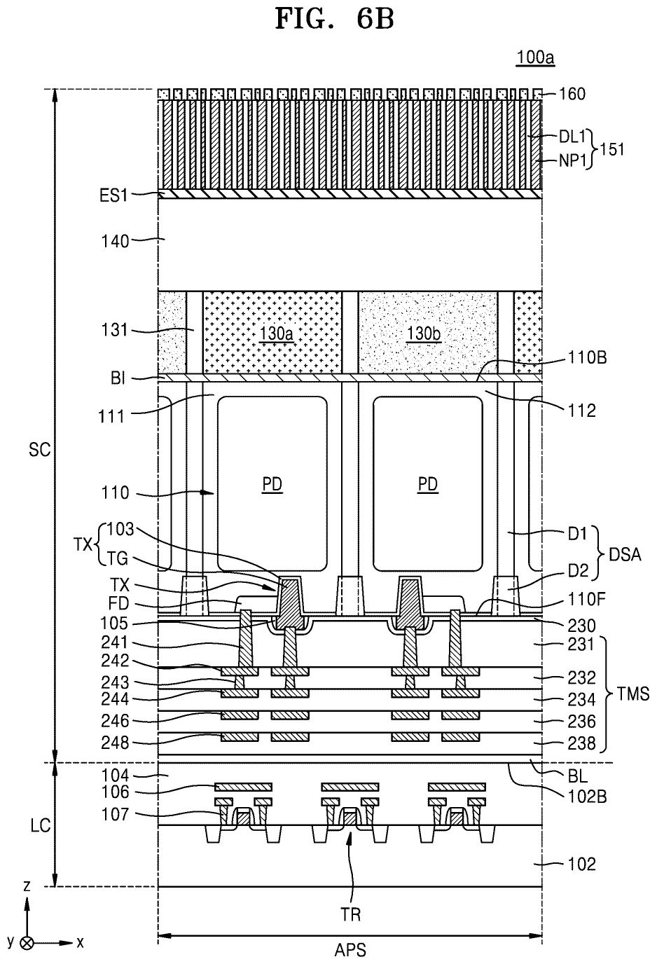

FIGS. 6A and 6B are cross-sectional views of an image sensor 100a according to an embodiment. In particular, FIG. 6B is a cross-sectional view of the image sensor 100a for describing one example of a wiring structure TMS of FIG. 6A.

FIGS. 6A and 6B illustrate some components of the active pixel sensor area APS in the sensor array area SA, which may be included in the second semiconductor chip SC of the image sensor 100 shown in FIG. 1, and some components of the first semiconductor chip LC, which overlap the active pixel sensor area APS in the vertical direction (the Z direction).

Referring to FIGS. 6A and 6B, in the image sensor 100a, the first semiconductor chip LC may be bonded to the second semiconductor chip SC by using a bonding layer BL. In the active pixel sensor area APS of the second semiconductor chip SC, a plurality of unit pixels PX configured to generate an active signal corresponding to wavelengths of light received from the outside may be arranged.

The image sensor 100a may be one embodiment corresponding to the image sensor 100 described with reference to FIGS. 1 to 5.

The image sensor 100a may include a sensor substrate 110. The sensor substrate 110 may include a semiconductor layer. In embodiments, the sensor substrate 110 may include a semiconductor layer doped with P-type impurities. For example, the sensor substrate 110 may include a semiconductor layer including silicon (Si), germanium (Ge), SiGe, a Group II-VI compound semiconductor, a Group III-V compound semiconductor, or a combination thereof. In embodiments, the sensor substrate 110 may include a P-type epitaxial semiconductor layer epitaxially grown from a P-type bulk silicon substrate.

The sensor substrate 110 may have a frontside surface 110F and a backside surface 110B opposite to each other. The sensor substrate 110 may include a plurality of unit pixels 111 and 112. Each of the plurality of unit pixels 111 and 112 may include a photodiode PD, a floating diffusion region FD, and a transfer transistor TX. The photodiode PD and the floating diffusion region FD may be disposed inside the sensor substrate 110. The photodiode PD may generate charges in proportional to the intensity of light incident from the outside. The generated charges from the photodiode PD may be transferred to and accumulated in the floating diffusion region FD. The charges transferred to the floating diffusion region FD may be applied to a source follow gate included in a unit pixel 111 or 112. The unit pixel 111 or 112 is described below in more detail.

One end of the transfer transistor TX may be connected to the photodiode PD, and the other end of the transfer transistor TX may be connected to the floating diffusion region FD. The transfer transistor TX may transfer the charges generated in the photodiode PD to the floating diffusion region FD.

As shown in FIG. 6B, the transfer transistor TX may include a transfer gate TG and a gate insulating layer 103. The sidewall of the transfer gate TG may be covered by an insulating spacer 105. The transfer gate TG may include a portion buried in the sensor substrate 110. The gate insulating layer 103 may be between the transfer gate TG and the sensor substrate 110.

A pixel separation structure DSA may include a main device separation layer D1 and a local device separation layer D2.

The main device separation layer D1 may have a structure passing from the frontside surface 110F of the sensor substrate 110 to the backside surface 110B of the sensor substrate 110 in the vertical direction (the Z direction) so as to limit the plurality of unit pixels 111 and 112.

The local device separation layer D2 may pass through only a portion of the sensor substrate 110 from the frontside surface 110F of the sensor substrate 110 in the vertical direction (the Z direction) and cover a partial sidewall of the main device separation layer D1 adjacent to the frontside surface 110F of the sensor substrate 110.

In the specification, the vertical direction (the Z direction) may indicate a direction perpendicular to the backside surface 110B of the sensor substrate 110. In embodiments, the main device separation layer D1 and the local device separation layer D2 may include same material. For example, the local device separation layer D2 may include a silicon oxide film. The present disclosure is not limited thereto. In an embodiment, the main device separation layer D1 and the local device separation layer D2 may include different materials.

As shown in FIG. 6B, an etch stop layer 230 covering the transfer gate TG may be disposed on the frontside surface 110F of the sensor substrate 110. The etch stop layer 230 may conformally cover the transfer gate TG, the gate insulating layer 103, the insulating spacer 105, the floating diffusion region FD, and the pixel separation structure DSA. The etch stop layer 230 may include silicon nitride (SiN), silicon oxynitride, or a combination thereof but is not limited thereto.

The wiring structure TMS may be disposed on the frontside surface 110F of the sensor substrate 110. For example, the wiring structure TMS may be disposed on the etch stop layer 230 on the frontside surface 110F.

The wiring structure TMS may include a plurality of interlayer insulating layers 231, 232, 234, 236, and 238 covering a plurality of transfer transistors TX, a plurality of via contacts 241 and 243 and a plurality of wiring layers 242, 244, 246, and 248 covered by the plurality of interlayer insulating layers 231, 232, 234, 236, and 238, and the bonding layer BL. Some of the plurality of via contacts 241 and 243 may electrically connect the floating diffusion region FD to some of the plurality of wiring layers 242, 244, 246, and 248.

The stacking numbers and arrangements of interlayer insulating layers 231, 232, 234, 236, and 238 and wiring layers 242, 244, 246, and 248 are not limited to the illustration of FIG. 6B and may be variously changed and modified in accordance with circumstances.

The plurality of wiring layers 242, 244, 246, and 248 may include conductive lines connected to a plurality of transistors electrically connected to the photodiode PD. An electrical signal converted by the photodiode PD may be transferred to the first semiconductor chip LC through the plurality of wiring layers 242, 244, 246, and 248.

In embodiments, each of the plurality of interlayer insulating layers 231, 232, 234, 236, and 238 may include a silicon oxide film, a SiN film, a silicon oxynitride film, a low-k dielectric material film having a permittivity lower than that of the silicon oxide film, or a combination thereof but is not limited thereto.

In embodiments, each of the plurality of via contacts 241 and 243 and the plurality of wiring layers 242, 244, 246, and 248 may include tungsten (W), copper (Cu), aluminum (Al), gold (Au), silver (Ag), or a combination thereof but is not limited thereto.

In FIGS. 6A and 6B, the first semiconductor chip LC may include a logic substrate 102 and a plurality of transistors TR disposed on the logic substrate 102. The plurality of transistors TR may constitute a logic circuit. In embodiments, the plurality of transistors TR may constitute a circuit configured to control transistors included in the second semiconductor chip SC.

An interlayer insulating layer 104 covering the plurality of transistors TR and a plurality of via contacts 107 and a plurality of wiring layers 106 covered by the interlayer insulating layer 104 may be disposed on the logic substrate 102. The plurality of transistors TR may be electrically connected to the plurality of wiring layers 106 via the plurality of via contacts 107. The interlayer insulating layer 104 may include a silicon oxide film, a SiN film, a silicon oxynitride film, a low-k dielectric material film having a permittivity lower than that of the silicon oxide film, or a combination thereof but is not limited thereto. Each of the plurality of via contacts 107 and the plurality of wiring layers 106 may include W, Cu, Al, Au, Ag, or a combination thereof but is not limited thereto.

Referring to FIGS. 6A and 6B, the image sensor 100a may include a backside insulating layer BI covering the backside surface 110B of the sensor substrate 110, a color filter array including first and second color filters 130a and 130b, a spacer 140, a first etch stopper ES1, a first color separation lens array 151, and an anti-reflective layer 160.

The image sensor 100a may include the sensor substrate 110, as described above. The sensor substrate 110 may include a plurality of first pixels 111 configured to sense light of a first wavelength and a plurality of second pixels 112 configured to sense light of a second wavelength that is different from the first wavelength. The first wavelength may be a green light range in a visible wavelength band. The second wavelength may be a red light range in the visible wavelength band. Although third pixels and fourth pixels are not shown in the drawings, the third pixels and the fourth pixels may be shown in a cross-sectional view in another horizontal direction. For example, a first pixel 111 and a second pixel 112 of the inventive concept may correspond to a third pixel and a fourth pixel.

A backside insulating layer BL may be disposed on a backside surface 102B of the logic substrate 102. The backside insulating layer BL may be formed in the active pixel sensor area APS, the optical black sensor area OBS (see FIG. 1), and the pad area PA (see FIG. 1).

The backside insulating layer BI may include silicon oxide, SiN, or a combination thereof. In particular, the backside insulating layer BI may be formed of an insulating material having excellent light transmissivity to improve light sensitivity in the active pixel sensor area APS.

The thickness of the backside insulating layer BI may be optimized by considering both an optical characteristic and an insulating characteristic. In an embodiment, the thickness of the backside insulating layer BI may be selected within a range of, for example, about 1000 Å to about 5000 Å. This thickness range may provide a sufficient insulating characteristic and optimize light transmittance.

The backside insulating layer BI may be formed through a chemical vapor deposition (CVD) or atomic layer deposition (ALD) process. In particular, when the ALD process is used, excellent step coverage and uniform thickness distribution may be obtained.

The backside insulating layer BI may be formed as, for example, a multi-layer structure. For example, the backside insulating layer BI may have a structure in which a silicon oxide layer and a SiN layer are alternately stacked. This multi-layer structure may further improve an insulating characteristic and an interface characteristic.

The image sensor 100a may include the first color filter 130a disposed above the first pixel 111 and the second color filter 130b disposed above the second pixel 112, the first color filter 130a and the second color filter 130b being disposed on the backside insulating layer BI. Although not shown in FIGS. 6A and 6B, the image sensor 100a may further include a third color filter disposed above a third pixel and a fourth color filter disposed above a fourth pixel. For example, the first color filter 130a and the fourth color filter may be green color filters that transmit only green light therethrough, the second color filter 130b may be a blue color filter that transmits only blue light therethrough, and the third color filter may be a red color filter that transmits only red light therethrough. When the first color separation lens array 151 performs not only simple light concentration but also color separation, light color-separated by a considerable degree by the first color separation lens array 151 travels toward the first pixel 111, the second pixel 112, the third pixel, and the fourth pixel, and thus, optical loss may be little even when the first and second color filters 130a and 130b are used. When the first and second color filters 130a and 130b are used, the color purity of the image sensor 100a may be further improved. However, the first and second color filters 130a and 130b are not essential components, and if the color separation efficiency of the first color separation lens array 151 is sufficiently high, the first and second color filters 130a and 130b may be omitted.

The image sensor 100a including pixel arrays described above has little optical loss due to a color filter (e.g., an organic color filter), and thus, even when the size of a pixel is small, a sufficient intensity of light may be provided to a pixel. Therefore, an ultra-high resolution subminiature high-sensitive image sensor having hundreds of millions or more of pixels may be manufactured. This ultra-high resolution subminiature high-sensitive image sensor may be employed in various high-performance optical devices or high-performance electronic devices. These electronic devices may be, for example, a smartphone, a portable phone, a cellular phone, a personal digital assistant (PDA), a laptop computer, a personal computer (PC), various portable devices, home appliances, a security camera, a medical camera, a vehicle, an Internet of Things (IoT) device, or other mobile or non-mobile computing devices and are not limited thereto.

Such an electronic device may further include, in addition to the image sensor 100a, a processor, e.g., an application processor (AP), configured to control the image sensor 100a and, through the processor, control a plurality of hardware or software components by driving an operating system or an application program and perform various kinds of data processing and operations. The processor may further include a graphics processing unit (GPU) and/or an image signal processor. When the image signal processor is included in the processor, an image (or a video) acquired by the image sensor 110a may be stored and/or output by using the processor.

The image sensor 100a may include a color filter fence 131 provided between the first color filter 130a and the second color filter 130b. The color filter fence 131 may prevent optical interference between adjacent color filters and improve color purity. The color filter fence 131 may be formed of an opaque material blocking light and may clearly define the boundary between the first and second color filters 130a and 130b. By using the color filter fence 131, color mixture of light passing through each color filter may be prevented, and color reproducibility may be improved.

As another example, the color filter fence 131 may be disposed in the center of each of the first color filter 130a and the second color filter 130b. For example, the first color filter 130a and the second color filter 130b may be formed while surrounding the outer circumferential surface of the color filter fence 131. Color filter fences 131 may be spaced apart from each other in the horizontal direction at the same intervals. The interval between the color filter fences 131 spaced apart from each other in the horizontal direction is not limited to the ones in the drawings.

The image sensor 100a may include the spacer 140 that is transparent and disposed on the first color filter 130a and the second color filter 130b.

The spacer 140 may be disposed between the sensor substrate 110 and the first color separation lens array 151 to maintain constant the distance between the sensor substrate 110 and the first color separation lens array 151.

The spacer 140 may include a material transparent with respect to visible light, for example, a dielectric material, such as silicon dioxide (SiO₂) or siloxane-based spin on glass (SOG), having a refractive index lower than that of a first nanopost NP1 of the first color separation lens array 151 and having a low absorption rate in a visible band.

The thickness of the spacer 140 may be determined based on the focal length of light concentrated by the first color separation lens array 151 and selected within, for example, about ½ times to about 1.5 times the focal length of light of a reference wavelength λ0.

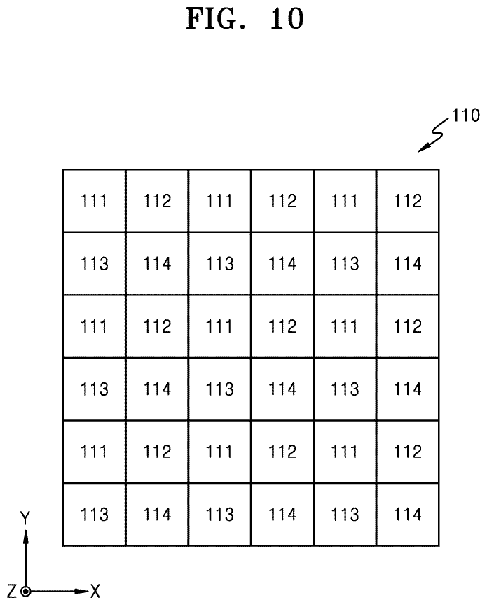

When it is assumed that the reference wavelength λ0 is 540 nm of green light, the pitch of a pixel (111, 112, 113, or 114 of FIG. 10) is 0.8 μm, and a refractive index n of the spacer 140 in the wavelength of 540 nm is 1.46, a focal length f of the green light, i.e., the distance between the lower surface of the first color separation lens array 151 and a point where the green light converges, may be about 1.64 μm, and the thickness of the spacer 140 may be selected within a range between about 0.82 μm and about 2.46 μm.

The first color separation lens array 151 may include first nanoposts NP1 supported by the spacer 140 and having a high refractive index by which the phase of incident light is changed and a first dielectric layer DL1 arranged between the first nanoposts NP1 and formed of a low-refractive dielectric having a refractive index lower than that of the first nanopost NP1. The dielectric material of the first dielectric layer DL1 may include, for example, air or SiO₂.

The image sensor 100a may include the first color separation lens array 151 and the first etch stopper ES1 disposed between the spacer 140 and the first color separation lens array 151.

The nanoposts NP1 may be dielectric or metallic pillar-like structures having lateral dimensions smaller than the wavelength of incident light. The nanoposts NP1 are configured to control the transmission, phase, polarization, or direction of incoming light on a per-pixel basis. The respective diameters, in the horizonal direction, of the first nanoposts NP1 may be different from each other. The shortest distances between the first nanoposts NP1 spaced apart from each other in the horizontal direction may be different from each other. The horizontal direction may be the X-direction or Y-direction.

The first color separation lens array 151 may not only concentrate incident light regardless of wavelengths but also change a phase for each wavelength of the incident light and concentrate the phase-changed light. In an embodiment, the first color separation lens array 151 may be partitioned into a green light concentration region for concentrating green light, a blue light concentration region for concentrating blue light, and a red light concentration region for concentrating red light.

The first color separation lens array 151 may include the first nanoposts NP1 of which the sizes, shapes, and/or arrangement are determined, such that green light separated from the incident light is concentrated on the first pixel 111, blue light separated from the incident light is concentrated on the second pixel 112, red light separated from the incident light is concentrated on the third pixel, and green light separated from the incident light is concentrated on the fourth pixel. The thickness of the first color separation lens array 151 in the vertical direction (the Z direction) may be similar to the height of the first nanopost NP1 and, for example, may be about 500 nm to about 1,500 nm.

To design the first color separation lens array 151 for color separation, a structure of green, blue, red, and infrared (IR) pixel corresponding regions may be optimized while evaluating the performance of a plurality of candidate color separation lens arrays on the basis of evaluation elements, such as a color separation spectrum, light efficiency, and a signal to noise ratio. For example, the structure of green, blue, red, and IR pixels corresponding regions may be optimized by predetermining a target numeric value of each evaluation element and then minimizing the sum of differences from the target numeric values of a plurality of evaluation elements. Alternatively, the performance for each evaluation element may be indexed, and the structure of green, blue, red, and IR pixels corresponding regions may be optimized such that a value indicating the performance is maximized.

The first color separation lens array 151 may further include at least one first etch stopper ES1 disposed beneath the first nanoposts NP1. Each first etch stopper ES1 may be disposed between a corresponding first nanopost NP1 and the spacer 140 to protect the spacer 140 from damage in a process of forming the first nanoposts NP1.

The first etch stopper ES1 may include a dielectric material that is transparent and has etch selectivity with respect to the spacer 140 in a patterning process of the first nanoposts NP1. For example, the first etch stopper ES1 may include at least one material selected from among aluminum oxide (AlO), hafnium oxide (HfO), and SiN.

The first etch stopper ES1 has a thickness enough to protect the spacer 140 in the patterning process, without affecting the optical characteristic of the first color separation lens array 151. The thickness of the first etch stopper ES1 may be, for example, about 3 nm to about 50 nm or about 5 nm to about 15 nm.

In another embodiment, to minimize an increase in reflectivity due to the first etch stopper ES1, the first etch stopper ES1 may be disposed so as not to fully cover the surface of the spacer 140. In other words, the first etch stopper ES1 may be disposed to cover only a portion of the upper surface of the spacer 140. For example, each first etch stopper ES1 may be disposed only beneath a first nanopost NP1 corresponding thereto, and because first etch stoppers ES1 are spaced apart from each other, in a region between every two first etch stoppers ES1, the upper surface of the spacer 140 may contact the lower surface of the first dielectric layer DL1. The term “contact,” as used herein, refers to a direct connection (i.e., physical touching) unless the context indicates otherwise.]

Because the refractive index of the spacer 140 is substantially the same as the refractive index of the first dielectric layer DL1, reflection hardly occurs on the interface between the spacer 140 and the first dielectric layer DL1. Therefore, by minimizing the total area of the first etch stoppers ES1, an increase in reflectivity on the interface between the spacer 140 and the first etch stopper ES1 may be minimized. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The image sensor 100a may include the anti-reflective layer 160 disposed on a light incident surface of the first color separation lens array 151.

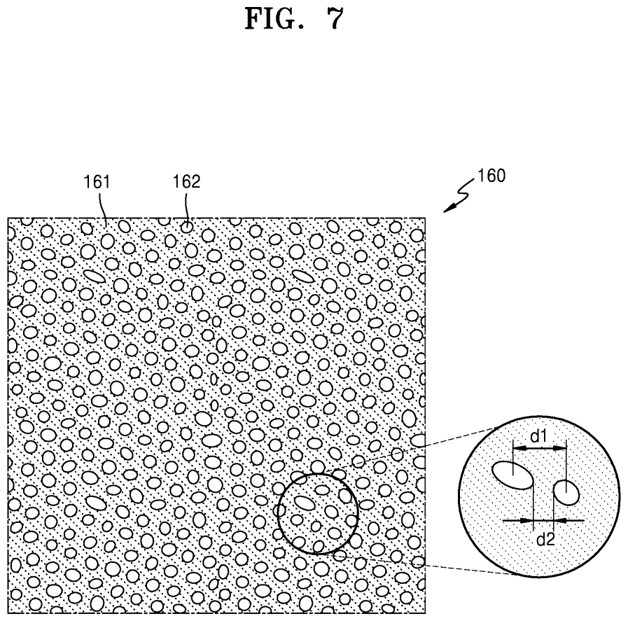

The anti-reflective layer 160 may be formed on the upper surface of the first color separation lens array 151 and include a pattern 162 (see FIG. 7) for reducing reflection of incident light. For example, the anti-reflective layer 160 may include a plurality of patterns of a nanoscale, and the plurality of patterns may have a quasi-periodic arrangement. In some embodiments, the plurality of patterns of the anti-reflective layer 160 may be randomly distributed in size or interval.

As described above, the first color separation lens array 151 may include the first nanoposts NP1 to separate each color component from the incident light. For example, the first nanoposts NP1 of the first color separation lens array 151 may have a periodic arrangement having a first pitch (i.e., a center-to-center distance of two adjacent first nanoposts NP1). Portions of the plurality of patterns of the anti-reflective layer 160 may overlap the first nanoposts NP1 in the vertical direction (Z-axis direction). The overlapping of the portions of the plurality of patterns of the anti-reflective layer 160 and the first nanoposts NP1 of the first color separation lens array 151 in the vertical direction (Z-axis direction) may indicate that at least portions of the plurality of patterns of the anti-reflective layer 160 are disposed on the first nanoposts NP1.

The plurality of patterns of the anti-reflective layer 160 may be disposed in consideration of overlapping with the first nanoposts NP1. For example, the plurality of patterns of the anti-reflective layer 160 overlapping the first nanoposts NP1 may be disposed to have various pitches (i.e., various center-to-center distances between two adjacent patterns overlapping corresponding first nanoposts NP1) that are different from the first pitch of the periodic arrangement of the first nanoposts NP1. At least one pattern that does not overlap any one of the first nanoposts NP1 may be disposed in or may be adjacent to a region between the two adjacent patterns overlapping corresponding first nanoposts NP1. In other words, some patterns, among the plurality of patterns, of the anti-reflective layer 160 overlapping corresponding first nanoposts among the first nanoposts NP1 may be aperiodically disposed. Accordingly, periodic overlapping between the plurality of patterns of the anti-reflective layer 160 and the first nanoposts NP1 may be avoided, and the occurrence of image artifacts such as Moiré pattern may be suppressed.

In some embodiments, the plurality of patterns of the anti-reflective layer 160 may have an average pitch. For example, the average of the distances between the plurality of patterns may be defined as the average pitch. The average pitch of the anti-reflective layer 160 may be less or greater than the first pitch of the first nanoposts NP1. In some embodiments, the average pitch of the anti-reflective layer 160 may not have an integer multiple relationship with the first pitch. For example, the ratio of the average pitch to the first pitch may not be an integer. Accordingly, the periodic overlapping between the plurality of patterns of the anti-reflective layer 160 and the first nanoposts NP1 may be prevented.

The plurality of patterns of the anti-reflective layer 160 may have a random shape. For example, a pattern may have a cylindrical shape, a polyprism shape, a conical shape, a polypyramid shape, or the like. In some embodiments, the plurality of patterns may have a curved surface. For example, a side surface of a pattern may have a concave curved surface or a convex curved surface. In some embodiments, the heights and widths of the plurality of patterns may be determined based on the wavelength of incident light.

FIG. 7 is a top view illustrating the anti-reflective layer 160 of an image sensor according to an embodiment.

Referring to FIG. 7, the anti-reflective layer 160 may include a plurality of patterns 162, and the plurality of patterns 162 may be disposed to have quasi-periodicity. For example, the plurality of patterns 162 may be arranged in a quasi-periodic manner, such that the distances between adjacent patterns vary according to a deterministic rule, without exhibiting a constant period. The plurality of patterns 162 may not be arranged in a periodic arrangement, but still follow a deterministic order that exhibits a form of long-range order without translational symmetry. In other words, the plurality of patterns 162 are not randomly distributed, yet they do not repeat at fixed intervals.

The pitch of the plurality of patterns 162 may be greater than the critical dimension (CD) of the plurality of patterns 162. The CD of the plurality of patterns 162 may be a distance d2 between the plurality of patterns 162. The pitch of the plurality of patterns 162 may be a distance d1 between the centers of the plurality of patterns 162. The pitch d1 of the plurality of patterns 162 may be the CD d2 of the plurality of patterns 162. To characterize the CD and pitch of the plurality of patterns 162 arranged in a quasi-periodic manner, a high-resolution imaging technique may be employed, such as scanning electron microscopy (SEM), atomic force microscopy (AFM), and optical microscopy. Using the obtained images, the distance d2 between adjacent patterns (i.e., nearest-neighbor distances) may be measured across multiple regions of the pattern to determine the CD. The measured CD values may then be statistically analyzed to determine a representative CD. In particular, the CD may be defined as an average value of the measured nearest-neighbor distances, accompanied by a standard deviation. Similarly, a center-to-center distance between two adjacent patterns may be measured across multiple regions to determine the pitch d1. In a quasi-periodic arrangement in which the patterns differ in size or spacing, a range or distribution of measured center-to-center distances is measured (e.g., using an average value and a standard deviation).

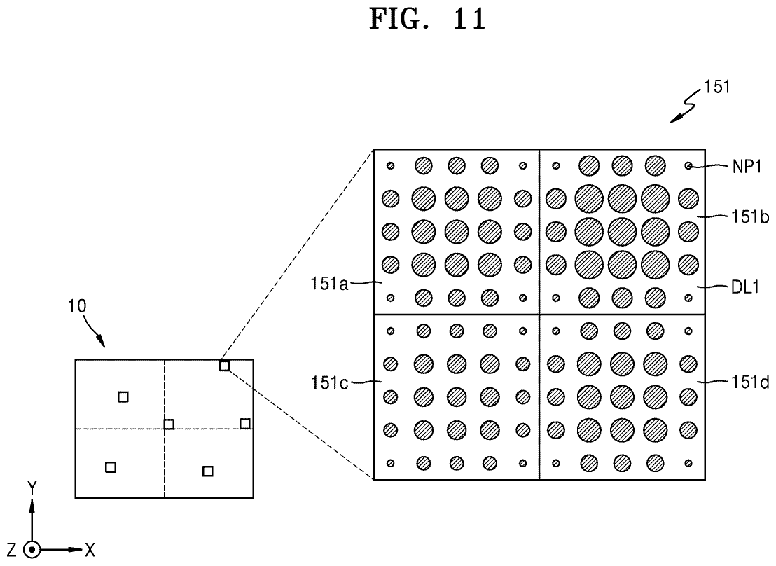

The density of the plurality of patterns 162 in the anti-reflective layer 160 may be uniform. For example, the density of patterns 162 in a random region of the anti-reflective layer 160 may be substantially the same as the density of patterns 162 in another region. In an embodiment, an area of each of the random region and the another random region may correspond to an area of one of first to fourth lenses 151a to 151d of FIG. 11. The density of the plurality of patterns 162 may be greater than 0 and less than 1. The density of the plurality of patterns 162 may be defined as the ratio of an area occupied by the plurality of patterns 162 with respect to a unit area of the anti-reflective layer 160. To determine the pattern density of a quasi-periodic arrangement, a high-resolution image of the patterned surface may be acquired using SEM, AFM, or optical microscopy. One or more regions of known area correspond to an area of one of first to fourth lenses 151a to 151d of FIG. 11, for example, may be selected from the image. The area of patterns within each region may be measured, and the local pattern density may be calculated as the area of patterns per unit area. A representative pattern density may be reported as an average value across the regions, with a standard deviation indicating variability due to the quasi-periodic arrangement.

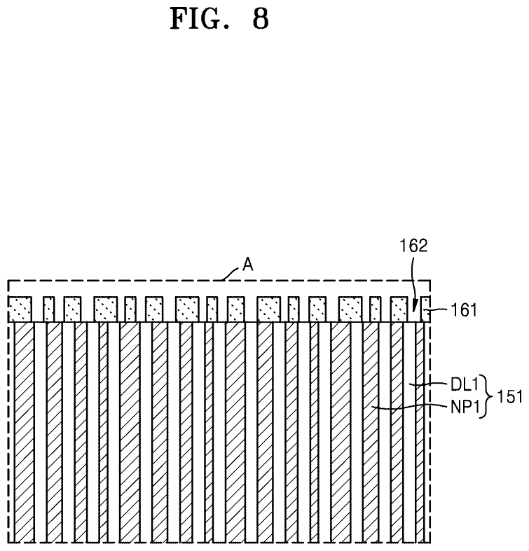

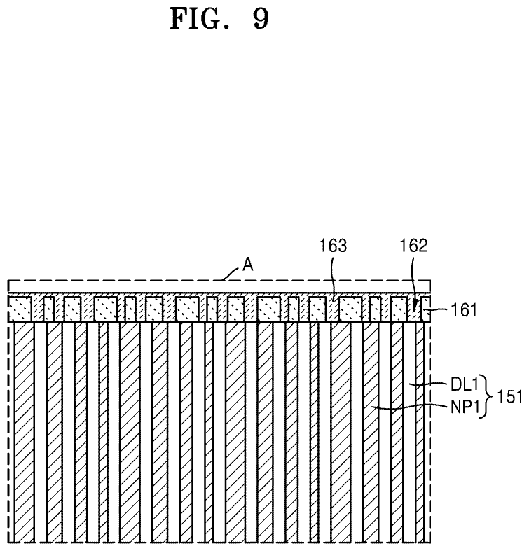

FIGS. 8 and 9 are enlarged views of a region A of FIG. 6A, according to embodiments.

FIG. 8 is an enlarged view illustrating the anti-reflective layer 160 according to an embodiment. Referring to FIG. 8, the anti-reflective layer 160 may include a base layer 161 and patterns 162. The patterns 162 may have an intaglio pattern formed in the base layer 161. The intaglio pattern is an engraved pattern in which the patterns, such as grooves, holes, trenches, and pits, are formed by removing material from an upper surface of the base layer 161, such that the patterned regions are recessed relative to the adjacent upper surface portions of the base layer 161. For example, a hole or trench formed by etching the base layer 161 may be defined as a pattern 162, and the inside of the pattern 162 may be filled with an air gap. As shown in FIGS. 7 and 8, the patterns 162 may be holes penetrating the base layer 161 and exposing the first color separation lens array 151.

In some embodiments, the patterns 162 may have a relief pattern protruding from the base layer 161. For example, a pillar-shaped structure formed on the base layer 161 may be defined as the pattern 162. Even when the pattern 162 is a relief pattern, a space between the patterns 162 may be filled with an air gap.

The air gap inside or between the patterns 162 may reduce the refractive index difference between the anti-reflective layer 160 and air, thereby reducing reflection of incident light. The shape of the pattern 162, such as an intaglio pattern and a relief pattern, may be determined by considering the easiness of a manufacturing process or the anti-reflection effect.

FIG. 9 is an enlarged view illustrating the anti-reflective layer 160 according to another embodiment. Referring to FIG. 9, the inside of the patterns 162 (e.g., holes as shown in FIGS. 7 and 8) may be filled with a certain material 163. For example, the certain material 163 may be a metal, a polymer, or oxide. In some embodiments, the refractive index of the certain material 163 may have a value between the refractive index of the anti-reflective layer 160 (i.e., the refractive index of the base layer 161) and the refractive index of air. Accordingly, the refractive index difference between the anti-reflective layer 160 and air may be reduced, thereby reducing reflection of incident light.

A density A of the patterns 162 in the anti-reflective layer 160 may satisfy Equation (1) below.

$$\sqrt{{n}_{l 1} \times {n}_{l 2}} = ( 1 - A ) {n}_{1} + A {n}_{2} \qquad ( 1 )$$

Herein, A denotes the density of the patterns 162, n₁₁ denotes the refractive index of a component (e.g., air) located on the anti-reflective layer 160, and n₁₂ denotes the refractive index of a component (e.g., a color separation lens array) located beneath the anti-reflective layer 160. In addition, n₁ may be the refractive index of the base layer 161, and n₂ may be the refractive index of the certain material disposed inside the pattern 162.

When the density A of the patterns 162 of the anti-reflective layer 160 satisfies Equation (1), the reflectivity of incident light may be minimized.

In some embodiments, as described above with reference to FIG. 8, when the pattern 162 includes an air gap, n₂ may correspond to the refractive index of air. In some embodiments, as described above with reference to FIG. 9, when the pattern 162 is filled with the certain material 163, n₂ may correspond to the refractive index of a metal, a polymer, or oxide that is the certain material 163.

By the density A satisfying Equation (1), the path of incident light passing through the anti-reflective layer 160 may be optimized, thereby minimizing reflection of the incident light.

FIG. 10 is a top view illustrating an arrangement of pixels in a pixel array.

FIG. 10 illustrates an arrangement of pixels when the pixel array 10 of the image sensor 100a has a Bayer pattern arrangement, as shown in FIG. 3. This arrangement is to sense incident light by separating the incident light into unit patterns, such as a Bayer pattern. For example, the first pixel 111 and a fourth pixel 114 may be green pixels configured to sense green light, the second pixel 112 may be a blue pixel configured to sense blue light, and a third pixel 113 may be a red pixel configured to sense red light. In a unit pattern of a 2×2 array form, the first pixel 111 and the fourth pixel 114 that are green pixels may be arranged in one diagonal direction, and the second pixel 112 and the third pixel 113 that are respectively a blue pixel and a red pixel may be arranged in the other diagonal direction.

FIG. 11 is a top view illustrating a color separation lens array included in an image sensor according to an embodiment.

Referring to FIG. 11, each of a plurality of first color separation lens arrays 151 arranged in the pixel array 10 may include first to fourth lenses 151a, 151b, 151c, and 151d, which only simply concentrate incident light on the first to fourth pixels 111, 112, 113, and 114 (see FIG. 10) without color separation, according to an embodiment. For example, the first to fourth lenses 151a, 151b, 151c, and 151d may simply concentrate incident light on the first to fourth pixels 111, 112, 113, and 114 (see FIG. 10), respectively, and color separation may occur in the first and second color filters 130a and 130b (see FIG. 6B). The first color separation lens array 151 may not only simply concentrate light but also change a phase for each wavelength of the light and concentrate the phase-changed light, according to an embodiment. In an embodiment, the phase of light of the first wavelength may be changed such that the phase-shifted light is concentrated on each first pixel 111, the phase of light of the second wavelength may be changed such that the phase-shifted light is concentrated on each second pixel 112, the phase of light of a third wavelength may be changed such that the phase-shifted light is concentrated on each third pixel 113, and the phase of light of a fourth wavelength may be changed such that the phase-shifted light is concentrated on each fourth pixel 114. Regardless of wavelength-based light concentration of the first color separation lens array 151, color separation may independently and duplicately occur in the first and second color filters 130a and 130b (see FIG. 6B).

In the description of FIG. 11 below, simple light concentration is additionally described. To concentrate incident light, a plurality of first nanoposts NP1 in each of the first to fourth lenses 151a, 151b, 151c, and 151d may be arranged in a symmetrical manner in the first direction (the X direction) and the second direction (the Y direction) with respect to the center of each of the first to fourth lenses 151a, 151b, 151c, and 151d. In particular, to make the greatest phase delay occur in the central region of each of the first to fourth lenses 151a, 151b, 151c, and 151d, first nanoposts NP1 arranged in the central region of each of the first to fourth lenses 151a, 151b, 151c, and 151d may have the largest diameter, and the diameter of a first nanopost NP1 may gradually decrease away from the central region of each of the first to fourth lenses 151a, 151b, 151c, and 151d. The first nanoposts NP1 may have cylindrical pillars, and the diameters of the cylindrical pillars may be variously distributed in each lens of the first to fourth lenses 151a, 151b, 151c, and 151d. The first dielectric layer DL1 may surround a side surface of each first nanopost of the first nanoposts NP1.

In the first color separation lens array 151 shown in FIG. 11, the first to fourth lenses 151a, 151b, 151c, and 151d may focus on first to fourth light-sensitive cells (e.g., the photodiodes PD) of the first to fourth pixels 111, 112, 113, and 114 as shown in FIGS. 6 and 10, respectively. In another embodiment, the first color separation lens array 151 may be configured to form a focus on each of the first to fourth light-sensitive cells of the first to fourth pixels 111, 112, 113, and 114 as shown in FIGS. 6 and 10.

The spacer 140 (see FIG. 6B) may provide a flat surface such that the first color separation lens array 151 is formed on the first and second color filters 130a and 130b (see FIG. 6B). In addition, the spacer 140 (see FIG. 6B) may provide the distance between the sensor substrate 110 (see FIG. 6B) and the first color separation lens array 151 together with the first and second color filters 130a and 130b (see FIG. 6B). The distance between the sensor substrate 110 (see FIG. 6B) and the first color separation lens array 151 may be determined by the focal length of the first color separation lens array 151. For example, the sum of the thickness of the spacer 140 (see FIG. 6B) and the thickness of the first and second color filters 130a and 130b (see FIG. 6B) may be the same as the focal length of the first color separation lens array 151. Then, light concentrated by the first color separation lens array 151 may be focused on the sensor substrate 110 (see FIG. 6B). If the focal length of the first color separation lens array 151 is sufficiently short, the spacer 140 (see FIG. 6B) may be omitted.

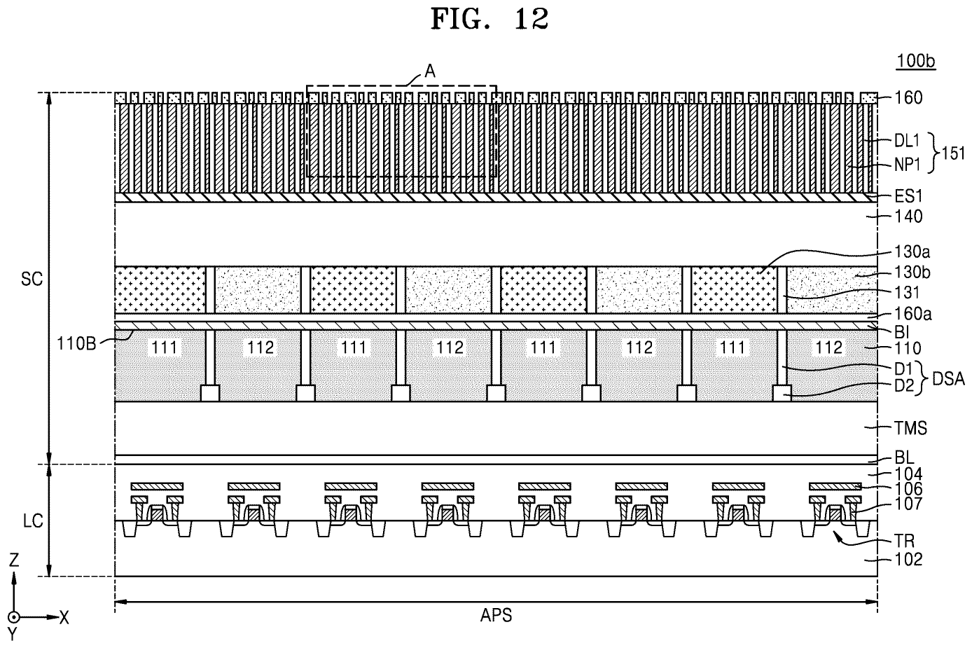

FIGS. 12 to 14 are cross-sectional views of partial areas of image sensors 100b, 100c, and 100d according to other embodiments.

Differences from FIG. 6A are mainly described with reference to FIGS. 12 to 14 together with FIG. 6A.

Referring to FIG. 12, the image sensor 100b according to another embodiment differs from the image sensor 100a shown in FIG. 6A in that the image sensor 100b may further include a lower anti-reflective layer 160a.

The image sensor 100b may include the lower anti-reflective layer 160a formed on the backside surface 110B of the sensor substrate 110. For example, the lower anti-reflective layer 160a may be formed on the backside insulating layer BI. The lower anti-reflective layer 160a may prevent light reflected from a photodiode from being incident back to the photodiode. Accordingly, crosstalk may be reduced, and the optical characteristic of the image sensor 100b may be improved.

The image sensor 100b of FIG. 12 differs from the image sensor 100a of FIG. 6A in that the image sensor 100b may further include the lower anti-reflective layer 160a on the sensor substrate 110. By forming both the lower anti-reflective layer 160a and an upper anti-reflective layer 160, the image sensor 100b may provide a further improved anti-reflection effect. For example, reflection from a photodiode may be reduced by the lower anti-reflective layer 160a, and reflection of incident light may be reduced by the upper anti-reflective layer 160.

The lower anti-reflective layer 160a and the upper anti-reflective layer 160 may be formed of the same material or different materials.

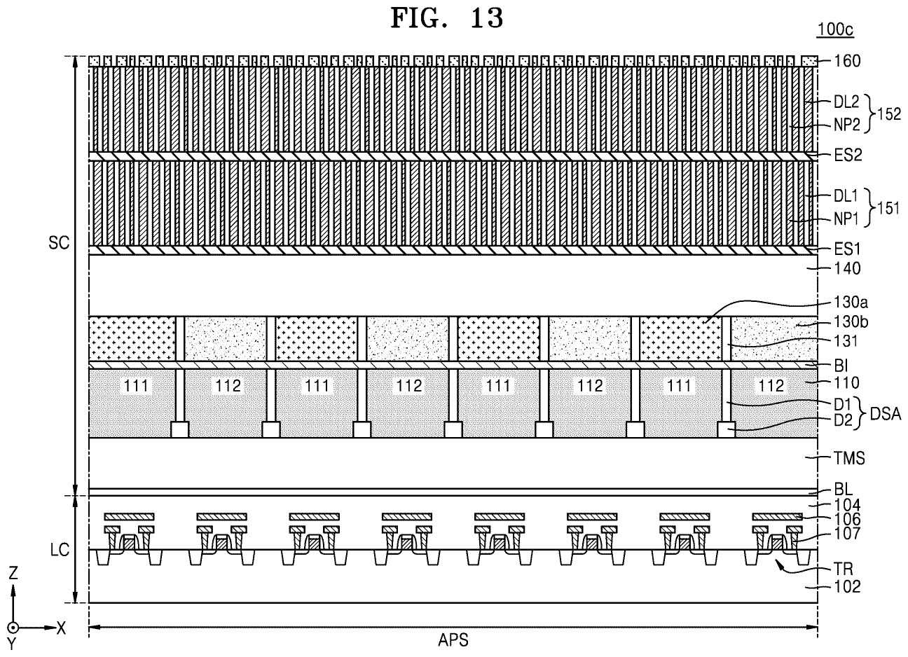

Referring to FIG. 13, the image sensor 100c may include two color separation lens arrays that are stacked. In an embodiment, the image sensor 100c may include the first color separation lens array 151 and a second color separation lens array 152. The second color separation lens array 152 may be disposed on the first color separation lens array 151. Incident light incident to the image sensor 100c may first pass through the second color separation lens array 152 and then pass through the first color separation lens array 151. The thickness of the first color separation lens array 151 may be substantially the same as the thickness of the second color separation lens array 152. The second color separation lens array 152 may include second nanoposts NP2 having a high refractive index to change the phase of the incident light and a second dielectric layer DL2 arranged between the second nanoposts NP2 and formed of a low-refractive dielectric having a refractive index lower than that of the second nanopost NP2. The second nanoposts NP2 and the second dielectric layer DL2 may include substantially the same materials as those of the first nanoposts NP1 and the first dielectric layer DL1, respectively. In an embodiment, the positions of the second nanoposts NP2 in the horizontal direction may differ from the positions of the first nanoposts NP1 in the horizontal direction. For example, unlike as shown in FIG. 13 in which the first nanopost NP1 is disposed under the second nanopost NP2, the first dielectric layer DL1 may be disposed under the second nanopost NP2. The second color separation lens array 152 may perform not only simple light concentration like the first color separation lens array 151 but also color separation. In an embodiment, the first color separation lens array 151 may perform light concentration only, and the second color separation lens array 152 may perform both light concentration and color separation. The image sensor 100c including the first color separation lens array 151 and the second color separation lens array 152 may perform a combination of a case where only light concentration is performed and a case where the phase of light of the first wavelength is changed such that the light of the first wavelength is concentrated on each first pixel and the phase of light of the second wavelength is changed such that the light of the second wavelength is concentrated on each second pixel may be formed.

In an embodiment, both the first color separation lens array 151 and the second color separation lens array 152 may only concentrate incident light. In an embodiment, both the first color separation lens array 151 and the second color separation lens array 152 may change the phase of incident light for each wavelength to concentrate the phase-changed incident light on each pixel corresponding to the wavelength of the incident light. In an embodiment, the first color separation lens array 151 may only concentrate all incident light, whereas the second color separation lens array 152 may change the phase of incident light for each wavelength to concentrate the phase-changed incident light on each pixel corresponding to the wavelength of the incident light. In an embodiment, the first color separation lens array 151 may change the phase of incident light for each wavelength to concentrate the phase-changed incident light on each pixel corresponding to the wavelength of the incident light, whereas the second color separation lens array 152 may only concentrate all incident light.

The image sensor 100c may further include a second etch stopper ES2 disposed between the first color separation lens array 151 and the second color separation lens array 152. The second etch stopper ES2 may be substantially the same as the first etch stopper ES1.

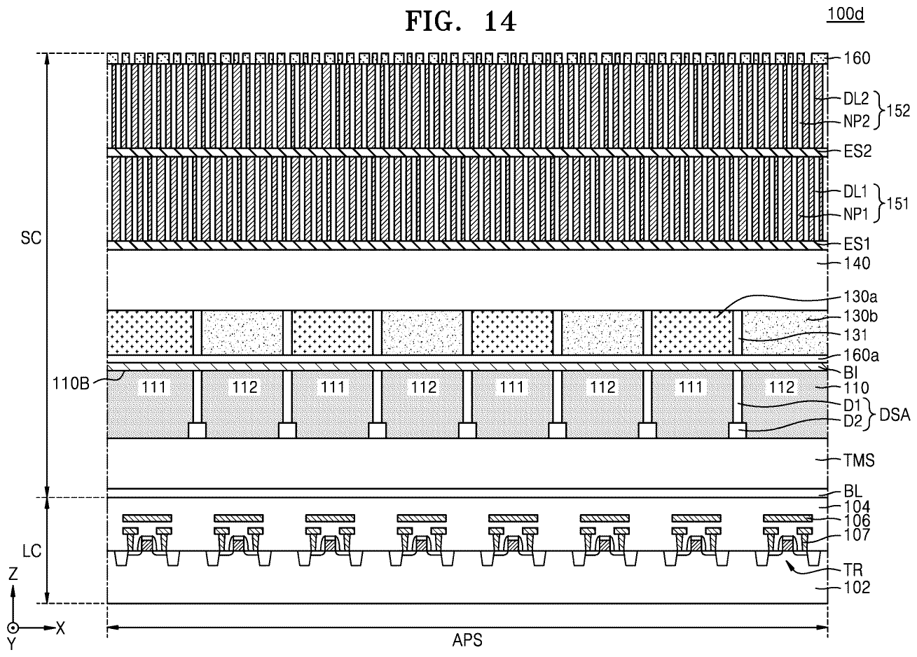

Referring to FIG. 14, the image sensor 100d may include the lower anti-reflective layer 160a formed on the backside surface 110B of the sensor substrate 110. For example, the lower anti-reflective layer 160a may be formed on the backside insulating layer BI. The lower anti-reflective layer 160a may prevent light reflected from a photodiode from being incident back to the photodiode. Accordingly, crosstalk may be reduced, and the optical characteristic of the image sensor 100d may be improved.

The image sensor 100d differs from the image sensor 100c of FIG. 13 in that the image sensor 100d further includes the lower anti-reflective layer 160a on the sensor substrate 110. By forming both the lower anti-reflective layer 160a and the upper anti-reflective layer 160, the image sensor 100d may provide a further improved anti-reflection effect. For example, reflection from a photodiode may be reduced by the lower anti-reflective layer 160a, and reflection of incident light may be reduced by the upper anti-reflective layer 160.

The lower anti-reflective layer 160a and the upper anti-reflective layer 160 may be formed of the same material or different materials.

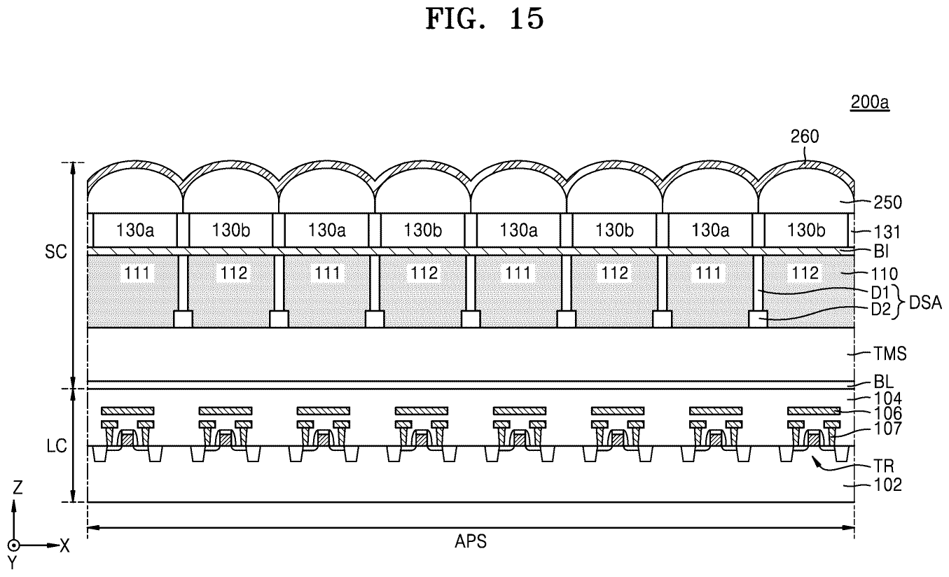

FIG. 15 is a cross-sectional view of a partial area of an image sensor 200a according to another embodiment.

Referring to FIG. 15, the image sensor 200a according to another embodiment may include the sensor substrate 110, the first and second color filters 130a and 130b, an optical lens array 250, and an anti-reflective layer 260. The image sensor 200a differs from the image sensor 100a of FIG. 6A in that the optical lens array 250 instead of the spacer 140 and the first color separation lens array 151 is disposed on the first and second color filters 130a and 130b.

The optical lens array 250 may be formed on the first and second color filters 130a and 130b and focus incident light to transfer the focused incident light to a photodiode. For example, the optical lens array 250 may include an array of convex lenses. A convex lens may refract incident light to focus the incident light on a photodiode, thereby improving the light sensitivity of the image sensor 200a.

The anti-reflective layer 260 may be formed on the optical lens array 250. As described above, the anti-reflective layer 260 may include a quasi-periodic pattern and reduce reflection of light incident to the optical lens array 250. Accordingly, the image sensor 200a may provide improved light sensitivity and image quality.

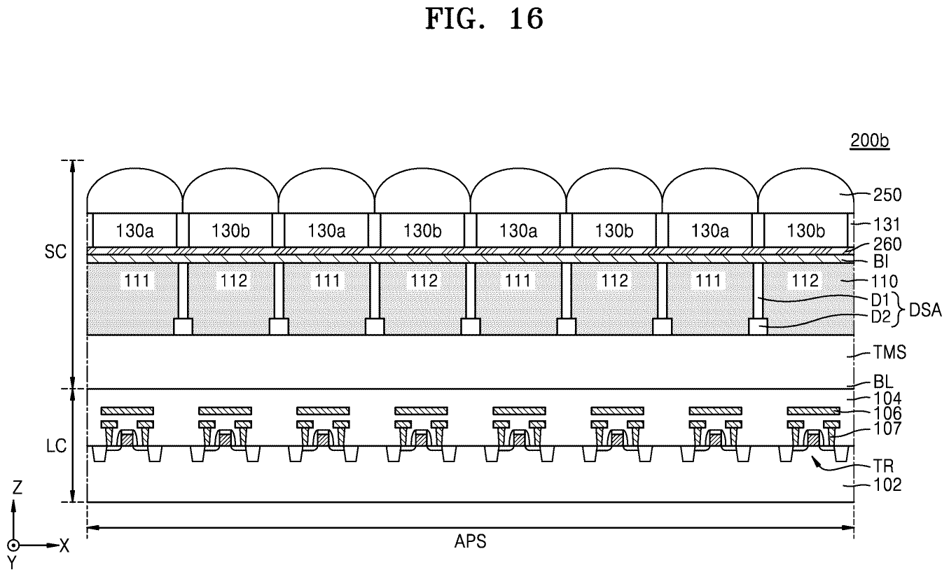

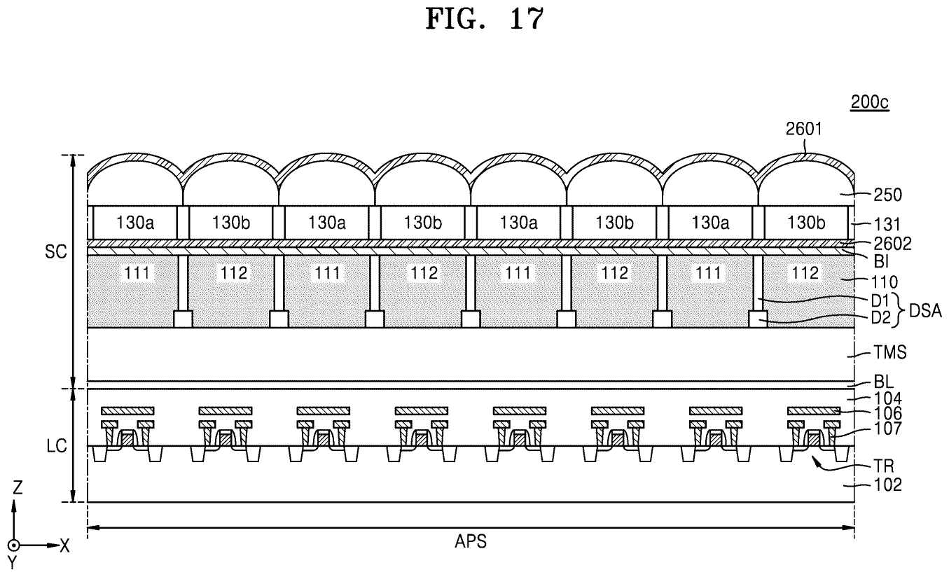

FIGS. 16 and 17 are cross-sectional views of partial areas of image sensors 200b and 200c according to other embodiments.

Referring to FIG. 16, the image sensor 200b may include the sensor substrate 110, the anti-reflective layer 260, the first and second color filters 130a and 130b, and the optical lens array 250. The image sensor 200b differs from the image sensor 100a of FIG. 6A in that the anti-reflective layer 260 is formed between the first and second color filters 130a and 130b and the sensor substrate 110 and no anti-reflective layer is formed on the optical lens array 250.

The anti-reflective layer 260 may reduce reflection of light, which may occur between the first and second color filters 130a and 130b and the sensor substrate 110. For example, the anti-reflective layer 260 may prevent light reflected from a photodiode from being reflected back by the first and second color filters 130a and 130b and incident to an adjacent photodiode.

The optical lens array 250 may be formed on the first and second color filters 130a and 130b and focus incident light to transfer the focused incident light to a photodiode. The light concentration effect of the optical lens array 250 and the anti-reflection effect of the anti-reflective layer 260 may be combined so as for the image sensor 200b to provide excellent image quality.

Referring to FIG. 17, the image sensor 200c may include the sensor substrate 110, the first and second color filters 130a and 130b, the optical lens array 250, an upper anti-reflective layer 2601, and a lower anti-reflective layer 2602. The image sensor 200c differs from the image sensor 200a of FIG. 15 in that the image sensor 200c further includes the lower anti-reflective layer 2602 formed between the sensor substrate 110 and the first and second color filters 130a and 130b.

The lower anti-reflective layer 2602 may reduce reflection of light, which may occur between the first and second color filters 130a and 130b and the sensor substrate 110. For example, the lower anti-reflective layer 2602 may prevent light reflected from a photodiode from being reflected back by the first and second color filters 130a and 130b and incident to an adjacent photodiode. Accordingly, the image sensor 200c may provide a further improved optical characteristic than the image sensor 200a.

The image sensor 200c may include both the upper anti-reflective layer 2601 and the lower anti-reflective layer 2602, thereby minimizing reflection of light and effectively reducing crosstalk. The light concentration effect of the optical lens array 250 and the anti-reflection effect of the upper and lower anti-reflective layers 2601 and 2602 may be combined so as for the image sensor 200c to provide excellent image quality.

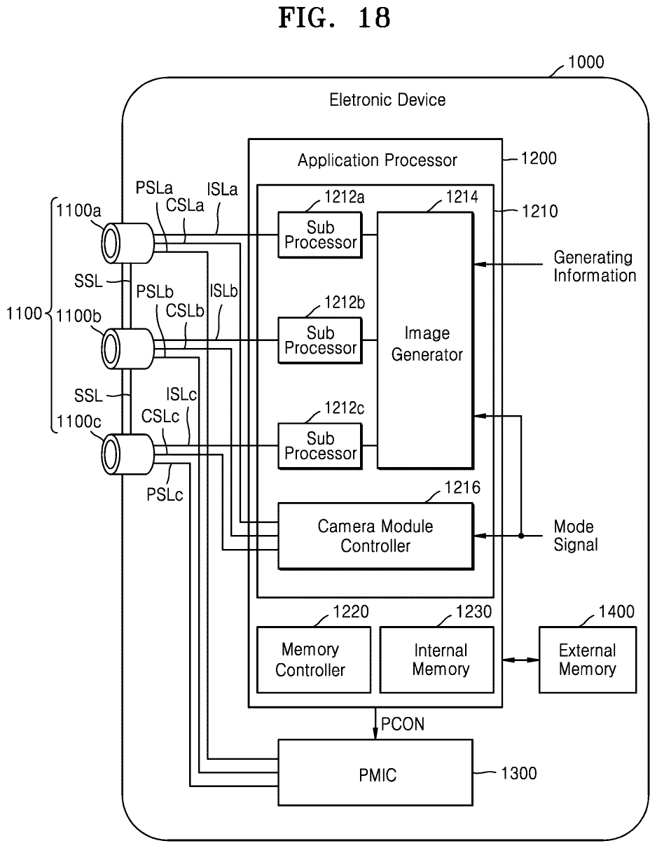

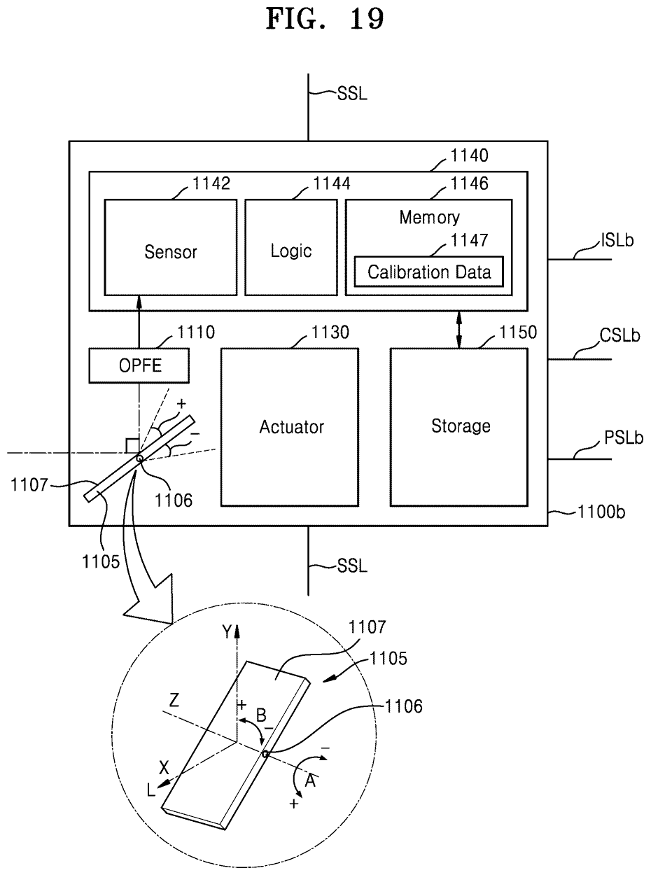

FIG. 18 is a block diagram of an electronic device 1000 including a multi-camera module. FIG. 19 is a detailed block diagram of a camera module 1100b of FIG. 18.

Referring to FIG. 18, the electronic device 1000 may include a camera module group 1100, an AP 1200, a power management integrated circuit (PMIC) 1300, and an external memory 1400.

The camera module group 1100 may include a plurality of camera modules 1100a, 1100b, and 1100c. Although FIG. 18 shows an embodiment in which three camera modules 1100a, 1100b, and 1100c are arranged, embodiments are not limited thereto. In some embodiments, the camera module group 1100 may be modified and include only two camera modules or n (n is a natural number of 4 or more) camera modules.

Referring to FIG. 19, the camera module 1100b may include a prism 1105, an optical path folding element (OPFE) 1110, an actuator 1130, an image sensing device 1140, and a storage 1150.

A detailed construction of the camera module 1100b is described below in more detail, and the description to be made below may also be applied to the other camera modules 1100a and 1100c.

The prism 1105 may include a reflective surface 1107 of a light reflective material to change the path of light L incident from the outside.

In some embodiments, the prism 1105 may change the path of the light L incident in the first direction (the X direction) to the second direction (the Y direction) that is perpendicular to the first direction (the X direction). In addition, the prism 1105 may change the path of the light L incident in the first direction (the X direction) to the second direction (the Y direction) that is perpendicular to the first direction (the X direction) by rotating the reflective surface 1107 of the light reflective material in an A direction around a central axis 1106 or rotating the central axis 1106 in a B direction. In this case, the OPFE 1110 may also move in the third direction (the Z direction) that is perpendicular to the first direction (the X direction) and the second direction (the Y direction).

In some embodiments, as shown in FIG. 19, the maximum rotating angle of the prism 1105 in the A direction may be 15 degrees or less in a +A direction and greater than 15 degrees in a −A direction, but the embodiments are not limited thereto.

In some embodiments, the prism 1105 may move at about 20 degrees, between about 10 degrees and about 20 degrees, or between about 15 degrees and about 20 degrees in a + or −B direction, wherein the moving angles in the + and −B directions may be the same or similar in a range of about one degree.

In some embodiments, the prism 1105 may move the reflective surface 1107 of the light reflective material in the third direction (the Z direction) parallel to an extending direction of the central axis 1106.

The OPFE 1110 may include, for example, a group of m (m is a natural number) optical lenses. The m optical lenses may move in the second direction (the Y direction) to change the optical zoom ratio of the camera module 1100b. For example, assuming that the default optical zoom ratio of the camera module 1100b is Z, if the m optical lenses included in the OPFE 1110 move, the optical zoom ratio of the camera module 1100b may change to 3Z, 5Z, or greater than 5Z.

The actuator 1130 may move the OPFE 1110 or the m optical lenses to a particular position. For example, the actuator 1130 may adjust the position of the m optical lenses such that an image sensor 1142 is positioned at the focal length of the m optical lenses for accurate sensing.

The image sensing device 1140 may include the image sensor 1142, a control logic 1144, and a memory 1146. The image sensor 1142 may sense an image of an object to be sensed, by using the light L provided through the optical lens. Accordingly, the surface reflectivity of the image sensor 1142 may be improved, thereby minimizing the occurrence of artifacts.

The control logic 1144 may control a general operation of the camera module 1100b. For example, the control logic 1144 may control an operation of the camera module 1100b in response to a control signal provided through a control signal line CSLb.

The memory 1146 may store information, such as calibration data 1147, required for an operation of the camera module 1100b. The calibration data 1147 may include information required for the camera module 1100b to generate image data by using the light L provided from the outside. The calibration data 1147 may include, for example, information regarding a degree of rotation, information regarding a focal length, information regarding an optical axis, and the like described above. When the camera module 1100b is implemented in the form of a multi-state camera of which the focal length varies according to a position of the m optical lenses, the calibration data 1147 may include a focal length value per position (or per state) of the m optical lenses and information regarding autofocusing.

The storage 1150 may store image data sensed by the image sensor 1142. The storage 1150 may be outside the image sensing device 1140 and be implemented in a stacked form with a sensor chip constituting the image sensing device 1140. In some embodiments, the storage 1150 may be implemented by electrically erasable programmable read-only memory (EEPROM), but the embodiments are not limited thereto.

Referring to FIGS. 18 and 19, in some embodiments, each of the plurality of camera modules 1100a, 1100b, and 1100c may include the actuator 1130. Accordingly, each of the plurality of camera modules 1100a, 1100b, and 1100c may include the same or different calibration data 1147 according to an operation of the actuator 1130 included therein.

In some embodiments, one (e.g., the camera module 1100b) of the plurality of camera modules 1100a, 1100b, and 1100c may be a folded lens-type camera module including the prism 1105 and the OPFE 1110 described above, and the other camera modules (e.g., the camera modules 1100a and 1100c) may be vertical-type camera modules in which the prism 1105 and the OPFE 1110 are not included, but the plurality of camera modules 1100a, 1100b, and 1100c are not limited thereto.

In some embodiments, one (e.g., the camera module 1100c) of the plurality of camera modules 1100a, 1100b, and 1100c may be, for example, a vertical-type depth camera configured to extract depth information by using an IR ray. In this case, the AP 1200 may generate a three-dimensional (3D) depth image by merging image data received from the depth camera with image data received from another camera module (e.g., the camera module 1100a or 1100b).

In some embodiments, at least two (e.g., the camera modules 1100a and 1100b) of the plurality of camera modules 1100a, 1100b, and 1100c may have different fields of view. In this case, for example, optical lenses of the at least two (e.g., the camera modules 1100a and 1100b) of the plurality of camera modules 1100a, 1100b, and 1100c may differ from each other but are not limited thereto.

In addition, in some embodiments, the fields of view of the plurality of camera modules 1100a, 1100b, and 1100c may differ from each other. In this case, the optical lenses respectively included in the plurality of camera modules 1100a, 1100b, and 1100c may also differ from each other but are not limited thereto.

In some embodiments, the plurality of camera modules 1100a, 1100b, and 1100c may be physically separated from each other. That is, instead that a sensing area of one image sensor 1142 is divided and used by the plurality of camera modules 1100a, 1100b, and 1100c, an independent image sensor 1142 may be inside each of the plurality of camera modules 1100a, 1100b, and 1100c. The image sensor 1142 may include an anti-reflective layer having a quasi-periodic pattern, as described above. Accordingly, the surface reflectivity of the image sensor 1142 may be improved, thereby minimizing the occurrence of artifacts.

Referring back to FIG. 18, the AP 1200 may include an image processing device 1210, a memory controller 1220, and an internal memory 1230. The AP 1200 may be implemented by being separated from the plurality of camera modules 1100a, 1100b, and 1100c. For example, the AP 1200 may be implemented by a separate semiconductor chip separated from the plurality of camera modules 1100a, 1100b, and 1100c.

The image processing device 1210 may include a plurality of sub-image processors 1212a, 1212b, and 1212c, an image generator 1214, and a camera module controller 1216.

The image processing device 1210 may include the plurality of sub-image processors 1212a, 1212b, and 1212c corresponding in number to the plurality of camera modules 1100a, 1100b, and 1100c.

Image data generated from the plurality of camera modules 1100a, 1100b, and 1100c may be provided to the plurality of sub-image processors 1212a, 1212b, and 1212c corresponding thereto through image signal lines ISLa, ISLb, and ISLc separated from each other, respectively. For example, image data generated by the camera module 1100a may be provided to the sub-image processor 1212a through the image signal line ISLa, image data generated by the camera module 1100b may be provided to the sub-image processor 1212b through the image signal line ISLb, and image data generated by the camera module 1100c may be provided to the sub-image processor 1212c through the image signal line ISLc. This image data transmission may be performed by using, for example, a camera serial interface (CSI) based on a mobile industry processor interface (MIPI) but is not limited thereto.

In some embodiments, one sub-image processor may correspond to a plurality of camera modules. For example, instead that the sub-image processor 1212a and the sub-image processor 1212c are separated from each other as shown in FIG. 18, the sub-image processor 1212a and the sub-image processor 1212c may be integrated into one sub-image processor, one of pieces of image data provided from the camera module 1100a and the camera module 1100c may be selected by a select element (e.g., a multiplexer) or the like and then provided to the integrated sub-image processor.

Image data provided to each sub-image processor 1212a, 1212b, or 1212c may be provided to the image generator 1214. The image generator 1214 may generate an output image by using the image data received from each sub-image processor 1212a, 1212b, or 1212c according to image generating information or a mode signal.

Particularly, the image generator 1214 may generate an output image by merging at least some of pieces of image data generated by the plurality of camera modules 1100a, 1100b, and 1100c having different fields of view, according to the image generating information or the mode signal. Alternatively, the image generator 1214 may generate an output image by selecting any one of pieces of image data generated by the plurality of camera modules 1100a, 1100b, and 1100c having different fields of view, according to the image generating information or the mode signal.

In some embodiments, the image generating information may include a zoom signal or a zoom factor. In addition, in some embodiments, the mode signal may be, for example, a signal based on a mode selected by a user.

If the image generating information is a zoom signal (zoom factor), and the plurality of camera modules 1100a, 1100b, and 1100c have different fields of view, the image generator 1214 may perform a different operation according to a type of the zoom signal. For example, if the zoom signal is a first signal, an output image may be generated by merging image data output from the camera module 1100a and image data output from the camera module 1100c and then using a merged image signal and image data output from the camera module 1100b not used for the merging. If the zoom signal is a second signal that is different from the first signal, the image generator 1214 may generate an output image by selecting one of image data output from the camera module 1100a, image data output from the camera module 1100b, and image data output from the camera module 1100c without performing the image data merging. However, the inventive concept is not limited thereto, and a method of processing image data may be modified and carried out according to circumstances.

In some embodiments, the image generator 1214 may receive a plurality of pieces of image data with different exposure times from at least one of the plurality of sub-image processors 1212a, 1212b, and 1212c and generate dynamic range-enhanced merged image data by performing high dynamic range (HDR) processing on the plurality of pieces of image data.

The camera module controller 1216 may provide a control signal to each of the plurality of camera modules 1100a, 1100b, and 1100c. The control signal generated by the camera module controller 1216 may be provided to corresponding camera modules 1100a, 1100b, and 1100c through control signal lines CSLa, CSLb, and CSLc separated from each other.

Any one (e.g., the camera module 1100b) of the plurality of camera modules 1100a, 1100b, and 1100c may be designated as a master camera module according to the image generating information including the zoom signal or to the mode signal, and the other camera modules (e.g., the camera modules 1100a and 1100c) may be designated as slave camera modules. This information may be included in the control signal and provided to corresponding camera modules 1100a, 1100b, and 1100c through the control signal lines CSLa, CSLb, and CSLc separated from each other.

Camera modules operating as a master and slaves may be changed according to the zoom factor or the mode signal. For example, if the field of view of the camera module 1100a is wider than the field of view of the camera module 1100b, and the zoom factor indicates a low zoom magnification, the camera module 1100b may operate as a master, and the camera module 1100a may operate as a slave. Otherwise, if the zoom factor indicates a high zoom magnification, the camera module 1100a may operate as a master, and the camera module 1100b may operate as a slave.

In some embodiments, the control signal provided from the camera module controller 1216 to each of the plurality of camera modules 1100a, 1100b, and 1100c may include a sync enable signal. For example, if the camera module 1100b is a master camera module, and the camera modules 1100a and 1100c are slave camera modules, the camera module controller 1216 may transmit the sync enable signal to the camera module 1100b. The camera module 1100b having received the sync enable signal may generate a sync signal based on the received sync enable signal and provide the generated sync signal to the camera modules 1100a and 1100c through a sync signal line SSL. The camera module 1100b and the camera modules 1100a and 1100c may be synchronized with the sync signal and transmit image data to the AP 1200.

In some embodiments, the control signal provided from the camera module controller 1216 to the plurality of camera modules 1100a, 1100b, and 1100c may include mode information according to the mode signal. Based on the mode information, the plurality of camera modules 1100a, 1100b, and 1100c may operate in a first operation mode or a second operation mode regarding a sensing rate.

In the first operation mode, the plurality of camera modules 1100a, 1100b, and 1100c may generate an image signal at a first speed (e.g., generate the image signal at a first frame rate), encode the image signal at a second speed higher than the first speed (e.g., encode the image signal at a second frame rate higher than the first frame rate), and transmit the encoded image signal to the AP 1200.

The AP 1200 may store the received image signal, i.e., the encoded image signal, in the internal memory 1230 or an external memory 1400 outside the AP 1200, then read the encoded image signal from the internal memory 1230 or the external memory 1400, decode the encoded image signal, and display image data generated based on the decoded image signal. For example, a corresponding sub-image processor among the plurality of sub-image processors 1212a, 1212b, and 1212c of the image processing device 1210 may perform decoding and perform image processing on a decoded image signal.

In the second operation mode, the plurality of camera modules 1100a, 1100b, and 1100c may generate an image signal at a third speed lower than the first speed (e.g., generate the image signal at a third frame rate lower than the first frame rate) and transmit the image signal to the AP 1200. The image signal provided to the AP 1200 may be a non-encoded signal. The AP 1200 may perform image processing on the received image signal or store the received image signal in the internal memory 1230 or the external memory 1400.

The PMIC 1300 may supply power, e.g., a power source voltage, to each of the plurality of camera modules 1100a, 1100b, and 1100c. For example, under control by the AP 1200, the PMIC 1300 may supply first power to the camera module 1100a through a power signal line PSLa, supply second power to the camera module 1100b through a power signal line PSLb, and supply third power to the camera module 1100c through a power signal line PSLc.

In response to a power control signal PCON from the AP 1200, the PMIC 1300 may generate power corresponding to each of the plurality of camera modules 1100a, 1100b, and 1100c and adjust a level of the power. The power control signal PCON may include a power adjustment signal for each operation mode of the plurality of camera modules 1100a, 1100b, and 1100c. For example, the operation mode may include a low power mode, and in the low power mode, the power control signal PCON may include information about a camera module operating in the low power mode and a set power level. Levels of power respectively provided to the plurality of camera modules 1100a, 1100b, and 1100c may be the same as or different from each other. In addition, the levels of power may be dynamically changed.

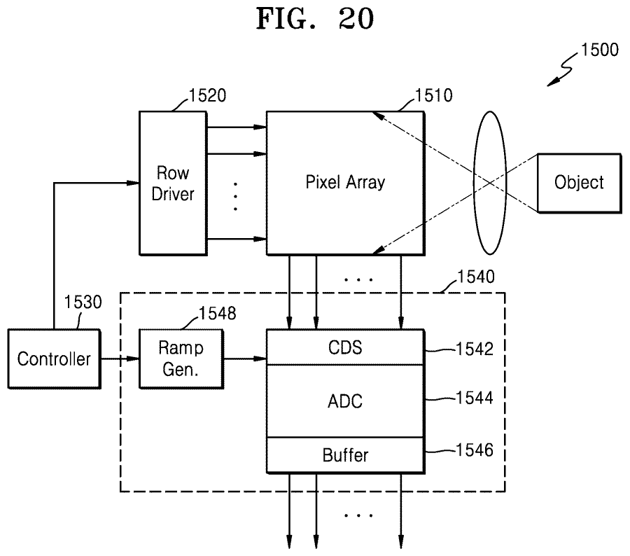

FIG. 20 is a block diagram illustrating an image sensor 1500 according to an embodiment.

Referring to FIG. 20, the image sensor 1500 may include a pixel array 1510, a controller 1530, a row driver 1520, and a pixel signal processor 1540.

The image sensor 1500 may include at least one of the images sensors 100, 100a, 100b, 100c, 100d, 200a, 200b, and 200c described above. The pixel array 1510 may include a plurality of unit pixels which are two-dimensionally arranged, and each unit pixel may include a photoelectric conversion device. The photoelectric conversion device may generate charges by absorbing light, and an electrical signal (output voltage) according to the generated charges may be provided to the pixel signal processor 1540 through a vertical signal line.

The plurality of unit pixels included in the pixel array 1510 may provide an output voltage one by one in a row unit, and accordingly, unit pixels belonging to one row of the pixel array 1510 may be activated at the same time by a select signal output from the row driver 1520. Unit pixels belonging to a selected row may provide an output voltage according to absorbed light to an output line of a corresponding column.

The controller 1530 may control the row driver 1520 such that the pixel array 1510 accumulates charges by absorbing light or temporarily stores the accumulated charges and outputs an electrical signal according to the stored charges to the outside of the pixel array 1510. In addition, the controller 1530 may control the pixel signal processor 1540 to measure the output voltage provided by the pixel array 1510.

The pixel signal processor 1540 may include a CDS 1542, an ADC 1544, and a buffer 1546. The CDS 1542 may sample and hold the output voltage provided by the pixel array 1510.

The CDS 1542 may double-sample a particular noise level and a level according to a generated output voltage and output a level corresponding to the difference therebetween. In addition, the CDS 1542 may receive a ramp signal generated by a ramp signal generator 1548 and output a comparison result through comparison.

The ADC 1544 may convert an analog signal into a digital signal corresponding to the level received from the CDS 1542. The buffer 1546 may latch the digital signal, and the latched signal may be sequentially output to the outside of the image sensor 1500 and transferred to an image processor (not shown).

The image sensor 1500 may include an anti-reflective layer having a quasi-periodic pattern, as described above. Accordingly, the surface reflectivity of the image sensor 1500 may be improved, thereby minimizing the occurrence of artifacts.

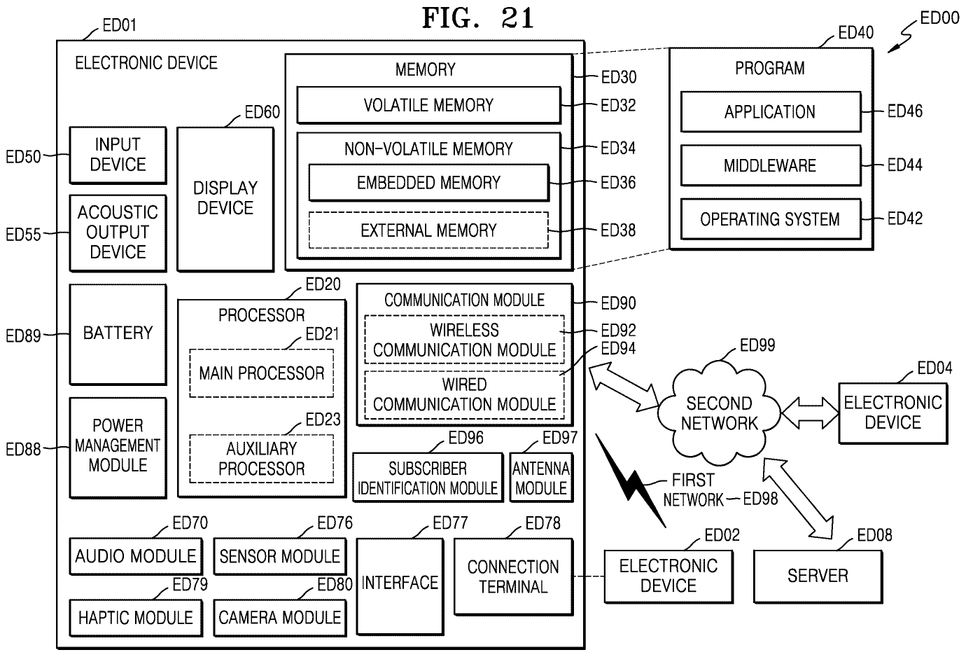

FIG. 21 is a block diagram schematically illustrating an electronic device ED01 including an image sensor according to embodiments.

Referring to FIG. 21, in a network environment ED00, the electronic device ED01 may communicate with another electronic device ED02 via a first network ED98 (a short-range wireless communication network or the like) or communicate with another electronic device ED04 and/or a server ED08 via a second network ED99 (a long-range wireless communication network or the like). The electronic device ED01 may communicate with the electronic device ED04 via the server ED08. The electronic device ED01 may include a processor ED20, a memory ED30, an input device ED50, an acoustic output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. Some of these components (e.g., the display device ED60) may be omitted from the electronic device ED01, or other components may be added to the electronic device ED01. Some of these components may be implemented as one integrated circuit. For example, the sensor module ED76 (a fingerprint sensor, an iris sensor, an illuminance sensor, or the like) may be implemented by being embedded in the display device ED60 (a display or the like).

The processor ED20 may execute software (a program ED40 or the like) to control one or more other components (hardware and software components) in the electronic device ED01, which are connected to the processor ED20, and perform various kinds of data processing or computation. As a portion of the data processing or computation, the processor ED20 may load a command and/or data received from another component (the sensor module ED76, the communication module ED90, or the like) onto a volatile memory ED32, process the command and/or data stored in the volatile memory ED32, and store result data in a non-volatile memory ED34. The processor ED20 may include a main processor ED21 (a central processing unit, an AP, or the like) and an auxiliary processor ED23 (a GPU, an image signal processor, a sensor hub processor, a communication processor, or the like) operable independently to or together with the main processor ED21. The auxiliary processor ED23 may use less power than the main processor ED21 and perform a specialized function.

The auxiliary processor ED23 may control a function and/or state related to some components (the display device ED60, the sensor module ED76, or the communication module ED90) among the components of the electronic device ED01, instead of the main processor ED21 while the main processor ED21 is in an inactive state (sleep state) or together with the main processor ED21 while the main processor ED21 is in an active state (application execution state). The auxiliary processor ED23 (the image signal processor, the communication processor, or the like) may be implemented as a portion of another component (the camera module ED80, the communication module ED90, or the like) functionally related to the auxiliary processor ED23.

The memory ED30 may store various data required by components (the processor ED20 or the sensor module ED76) of the electronic device ED01. The data may include, for example, software (the program ED40 or the like) and input data and/or output data related to a command related to the software. The memory ED30 may include the volatile memory ED32 and/or the non-volatile memory ED34. The non-volatile memory ED34 may include an embedded memory ED36 fixedly mounted in the electronic device ED01 and a detachable external memory ED38.

The program ED40 may be stored as software in the memory ED30 and include an operating system ED42, middleware ED44, and/or an application ED46.

The input device ED50 may receive, from the outside (a user or the like) of the electronic device ED01, a command and/or data to be used for a component (the processor ED20 or the like) of the electronic device ED01. The input device ED50 may include a microphone, a mouse, a keyboard, and/or a digital pen (a stylus pen or the like).

The acoustic output device ED55 may output an acoustic signal to the outside of the electronic device ED01. The acoustic output device ED55 may include a speaker and/or a receiver. The speaker may be used for a general use, such as multimedia playback or recording playback, and the receiver may be used to receive an incoming call. The receiver may be coupled as a part of the speaker or implemented as an independent separate device.

The display device ED60 may visually provide information to the outside of the electronic device ED01. The display device ED60 may include a display, a hologram device, or a projector and include a control circuit configured to control a corresponding device. The display device ED60 may include touch circuitry configured to sense a touch and/or sensor circuitry (a pressure sensor or the like) configured to measure the strength of a force generated by the touch.

The audio module ED70 may convert a sound into an electrical signal or reversely convert an electrical signal into a sound. The audio module ED70 may acquire a sound through the input device ED50 or output a sound through the acoustic output device ED55 and/or a speaker and/or headphones of another electronic device (the electronic device ED02 or the like) directly or wirelessly connected to the electronic device ED01.

The sensor module ED76 may sense an operating state (power, a temperature, or the like) or an external environmental state (a user state or the like) of the electronic device ED01 and generate an electrical signal and/or a data value corresponding to the sensed state. The sensor module ED76 may include a gesture sensor, a gyro sensor, an atmospheric pressure sensor, a magnetic sensor, an acceleration sensor, a grip sensor, a proximity sensor, a color sensor, an IR sensor, a biometric sensor, a temperature sensor, a humidity sensor, and/or an illuminance sensor.

The interface ED77 may support one or more designated protocols usable to directly or wirelessly connect the electronic device ED01 to another electronic device (the electronic device ED02 or the like). The interface ED77 may include a high definition multimedia interface (HDMI), a universal serial bus (USB) interface, a secure digital (SD) card interface, and/or an audio interface.

A connection terminal ED78 may include a connector capable of physically connecting the electronic device ED01 to another electronic device (the electronic device ED02 or the like). The connection terminal ED78 may include an HDMI connector, a USB connector, an SD card connector, and/or an audio connector (a headphones connector or the like).

The haptic module ED79 may convert an electrical signal into a mechanical stimulus (vibration, movement, or the like) or an electrical stimulus recognizable by the user through tactile or motor sensation. The haptic module ED79 may include a motor, a piezoelectric element, and/or an electrical stimulation device.

The camera module ED80 may capture a still image or a moving picture. The camera module ED80 may include a lens assembly including one or more lenses, the image sensor 100 of FIG. 1, image signal processors, and/or flashes. The lens assembly included in the camera module ED80 may collect light emitted from a subject of which an image is to be captured.

The power management module ED88 may manage power to be supplied to the electronic device ED01. The power management module ED88 may be implemented as a part of a PMIC.

The battery ED89 may supply power to the components of the electronic device ED01. The battery ED89 may include a non-rechargeable primary battery, a rechargeable secondary battery, and/or a fuel cell.

The communication module ED90 may establish a direct (wired) communication channel and/or a wireless communication channel between the electronic device ED01 and another electronic device (the electronic device ED02, the electronic device ED04, the server ED08, or the like) and support communication through the established communication channel. The communication module ED90 may include one or more communication processors operated independently to the processor ED20 (an AP or the like) and supporting direct communication and/or wireless communication. The communication module ED90 may include a wireless communication module ED92 (a cellular communication module, a short-range wireless communication module, a global navigation satellite system (GNSS), or the like) and/or a wired communication module ED94 (a local area network (LAN) communication module, a power line communication module, or the like). A corresponding communication module among these communication modules may communicate with another electronic device via the first network ED98 (a short-range communication network, such as Bluetooth, WiFi Direct, or infrared data association (IrDA)) or the second network ED99 (a long-range communication network, such as a cellular network, the Internet, or a computer network (a LAN, a wide area network (WAN), or the like). These various types of communication modules may be integrated into one component (a single chip) or implemented as a plurality of separate components (a plurality of chips). The wireless communication module ED92 may identify and authenticate the electronic device ED01 in a communication network, such as the first network ED98 and/or the second network ED99, by using subscriber information (an international mobile subscriber identity (IMSI) or the like) stored in the subscriber identification module ED96.

The antenna module ED97 may transmit or receive a signal and/or power to or from the outside (another electronic device or the like). An antenna may include a radiator including a conductive pattern formed on a substrate (a printed circuit board (PCB) or the like). The antenna module ED97 may include one or more antennas. When a plurality of antennas are included, an antenna suitable for a communication scheme used in a communication network, such as the first network ED98 and/or the second network ED99, may be selected from among the plurality of antennas by the communication module ED90. Through the selected antenna, a signal and/or power may be exchanged between the communication module ED90 and another electronic device. Besides an antenna, other components (a radio frequency integrated circuit (RFIC)) may be included as a part of the antenna module ED97.

Some of the components may be connected to each other and exchange a signal (a command, data, or the like), through a communication scheme (a bus, a general purpose input and output (GPIO) interface, a serial peripheral interface (SPI), a mobile industry processor interface (MIPI), or the like) between peripheral devices.

A command or data may be exchanged between the electronic device ED01 and the electronic device ED04 via the server ED08 connected to the second network ED99. The electronic devices ED02 and ED04 may be the same or different types as or from that of the electronic device ED01. All or some of operations executed in the electronic device ED01 may be executed in one or more devices among the other electronic devices (e.g., the electronic device ED02, the electronic device ED04, and the server ED08). For example, when the electronic device ED01 needs to perform a certain function or service, the electronic device ED01 may request one or more other electronic devices to perform a portion or all of the function or service, instead of executing the function or service by the electronic device ED01. The one or more other electronic devices having received the request may execute an additional function or service related to the request and transmit a result of the execution to the electronic device ED01. To this end, cloud computing, distributed computing, and/or client-server computing technologies may be used.

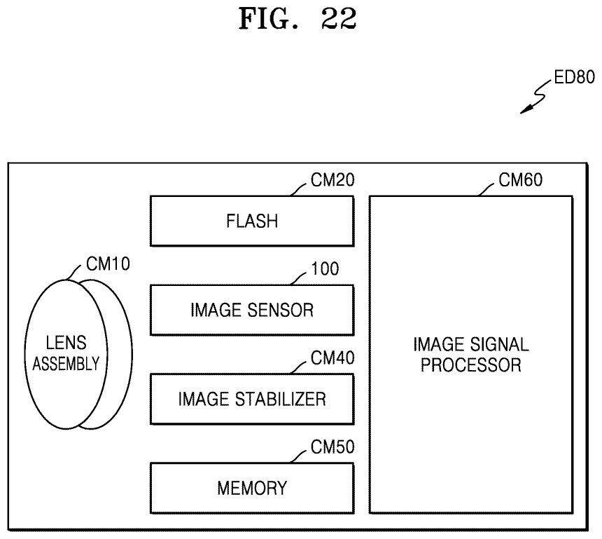

FIG. 22 is a block diagram schematically illustrating the camera module ED80 of FIG. 21.

Referring to FIG. 22, the camera module ED80 may include a lens assembly CM10, a flash CM20, an image sensor 100 (the image sensor 100 of FIG. 1 or the like), an image stabilizer CM40, a memory CM50 (a buffer memory or the like), and/or an image signal processor CM60. The lens assembly CM10 may collect light emitted from a subject of which an image is to be captured. The camera module ED80 may include a plurality of lens assemblies CM10, and in this case, the camera module ED80 may be referred to as a dual camera, a 360-degree camera, or a spherical camera. Some of the plurality of lens assemblies CM10 may have the same lens attributes (a view angle, a focal length, autofocusing, an F number, or optical zoom) or different lens attributes. The lens assembly CM10 may include a wide-angle lens or a telephoto lens.

The flash CM20 may emit light used to reinforce light emitted or reflected from a subject. The flash CM20 may include one or more light-emitting diodes (LEDs) (a red-green-blue (RGB) LED, a white LED, an IR LED, an ultraviolet (UV) LED, or the like) and/or a xenon lamp. The image sensor 100 may be the image sensor 100 described with reference to FIG. 1 and may acquire an image corresponding to a subject by converting, into an electrical signal, light emitted or reflected from the subject and transferred through the lens assembly CM10. The image sensor 100 may include one or more sensors selected from image sensors, such as an RGB sensor, a black and white (BW) sensor, an IR sensor, and a UV sensor, having different attributes. Each of the sensors included in the image sensor 100 may be implemented by a charge-coupled device (CCD) sensor and/or a CMOS sensor. The image sensor 100 may include an anti-reflective layer having a quasi-periodic pattern, as described above. Accordingly, the surface reflectivity of the image sensor 100 may be improved, thereby minimizing the occurrence of artifacts.

The image stabilizer CM40 may compensate for a negative effect due to movement of the camera module ED80 or the electronic device ED01 (see FIG. 21) including the same by moving the one or more lenses included in the lens assembly CM10 or the image sensor 100 in a particular direction or controlling an operating characteristic of the image sensor 100 (adjusting a read-out timing) in response to the movement. The image stabilizer CM40 may sense the movement of the camera module ED80 or the electronic device ED01 (see FIG. 21) by using a gyro sensor (not shown) or an acceleration sensor (not shown) provided inside or outside the camera module ED80. The image stabilizer CM40 may be optically implemented.

The memory CM50 may store, for a subsequent image processing work, partial or whole data of an image acquired using the image sensor 100. For example, when a plurality of images are acquired at a high speed, acquired original data (Bayer-patterned data, high-resolution data, or the like) may be stored in the memory CM50, only a low-resolution image may be displayed, and then original data of a selected (user-selected or the like) image may be transferred to the image signal processor CM60. The memory CM50 may be integrated with the memory ED30 (see FIG. 21) of the electronic device ED01 (see FIG. 21) or implemented as a separate memory that is independently operated.

The image signal processor CM60 may perform image processing on an image acquired through the image sensor 100 or image data stored in the memory CM50. The image processing may include depth map generation, 3D modeling, panoramic image generation, feature point extraction, image synthesis, and/or image compensation (noise reduction, resolution adjustment, brightness adjustment, blurring, sharpening, softening, or the like). The image signal processor CM60 may perform control (exposure time control, read-out timing control, or the like) on components (the image sensor 100) included in the camera module ED80. An image processed by the image signal processor CM60 may be stored back in the memory CM50 for additional processing or provided to an external component (the memory ED30 (see FIG. 21), the display device ED60 (see FIG. 21), the electronic device ED02 (see FIG. 21), the electronic device ED04 (see FIG. 21), the server ED08 (see FIG. 21), or the like) of the camera module ED80. The image signal processor CM60 may be integrated with the processor ED20 (see FIG. 21) or implemented as a separate process that is independently operated to the processor ED20 (see FIG. 21). When the image signal processor CM60 is a separate processor from the processor ED20 (see FIG. 21), an image processed by the image signal processor CM60 may undergo additional image processing and then be displayed through the display device ED60 (see FIG. 21).

The electronic device ED01 (see FIG. 21) may include a plurality of camera modules ED80 having different attributes or functions. In this case, one of the plurality of camera modules ED80 may be a wide-angle camera, and another one of the plurality of camera modules ED80 may be a telephoto camera. Similarly, one of the plurality of camera modules ED80 may be a front camera, and another one of the plurality of camera modules ED80 may be a rear camera.

While the inventive concept has been particularly shown and described with reference to embodiments thereof, it will be understood that various changes in form and details may be made therein without departing from the spirit and scope of the following claims.

What is claimed is:

1. An image sensor comprising:
a sensor substrate including a first pixel configured to sense light of a first wavelength and a second pixel configured to sense light of a second wavelength that is different from the first wavelength;
a color filter array including a first color filter and a second color filter and disposed on the sensor substrate, wherein the first color filter and the second color filter overlap the first pixel and the second pixel, respectively;
a spacer that is transparent and disposed on the first color filter and the second color filter;
a first color separation lens array disposed on the spacer and configured to:
change a phase of the light of the first wavelength such that the light of the first wavelength is concentrated on the first pixel, and
change a phase of the light of the second wavelength such that the light of the second wavelength is concentrated on the second pixel; and
an anti-reflective layer located at least one of:
on an upper surface of the first color separation lens array,
between the spacer and the color filter array, and
between the color filter array and the sensor substrate,
wherein the anti-reflective layer has a plurality of patterns that are arranged in a quasi-periodic manner.

2. The image sensor of claim 1,
wherein, in the anti-reflective layer, an average pitch of the plurality of patterns is greater than an average critical dimension (CD) of the plurality of patterns.

3. The image sensor of claim 1,
wherein, in the anti-reflective layer, a density of the plurality of patterns is uniform over a plurality of regions of the anti-reflective layer.

4. The image sensor of claim 1,
wherein, in the anti-reflective layer, a density of the plurality of patterns is greater than 0 and less than 1.

5. The image sensor of claim 1,
wherein the anti-reflective layer comprises a base layer with a plurality of engraved patterns which correspond to the plurality of patterns,
wherein a material is disposed in the plurality of patterns, and
wherein the material disposed in the plurality of patterns includes air, a metal, a polymer, or oxide.

6. The image sensor of claim 5,
wherein a density of the plurality of patterns of the anti-reflective layer satisfies Equation (1):
$$\sqrt{{n}_{l 1} \times {n}_{l 2}} = ( 1 - A ) {n}_{1} + A {n}_{2} , \qquad ( 1 )$$
where:
A denotes the density of the plurality of patterns,
n₁₁ denotes a refractive index of a component located on the anti-reflective layer,
n₁₂ denotes a refractive index of a component located beneath the anti-reflective layer,
n₁ is a refractive index of the base layer, and
n₂ is a refractive index of the material disposed inside the plurality of patterns.

7. The image sensor of claim 1,
wherein the first color separation lens array comprises:
a plurality of first nanoposts; and
a first dielectric layer surrounding a side surface of each first nanopost of the plurality of first nanoposts and including a dielectric material having a refractive index lower than a refractive index of a material of the plurality of first nanoposts.

8. The image sensor of claim 7,
wherein the plurality of first nanoposts, when viewed in a plan view, periodically spaced apart from each other at a first pitch which corresponds to a center-to-center distance of two adjacent first nanoposts of the plurality of first nanoposts, and
wherein some patterns of the plurality of patterns which are arranged in the quasi-periodic manner aperiodically overlap some first nanoposts of the plurality of first nanoposts.

9. The image sensor of claim 7, further comprising:
an etch stopper disposed between the spacer and the first color separation lens array.

10. The image sensor of claim 1, further comprising:
a second color separation lens array stacked on the first color separation lens array,
wherein the first color separation lens array comprises:
a plurality of first nanoposts; and
a first dielectric layer surrounding a side surface of each first nanopost of the plurality of first nanoposts and including a dielectric material having a refractive index lower than a refractive index of a material of the plurality of first nanoposts,
wherein the second color separation lens array comprises:
a plurality of second nanoposts; and
a second dielectric layer surrounding each second nanopost of the plurality of second nanoposts and including a dielectric material having a refractive index lower than a refractive index of a material of the plurality of second nanoposts, and
wherein an arrangement of the plurality of first nanoposts is different from an arrangement of the plurality of second nanoposts.

11. An image sensor comprising:
a sensor substrate including a pixel configured to sense light;
a color filter disposed on the sensor substrate and overlapping the pixel;
an optical lens array disposed on the color filter and configured to concentrate the light on the pixel; and
an anti-reflective layer located at least one of:
on the optical lens array,
between the optical lens array and the color filter, and
between the color filter and the sensor substrate,
wherein the anti-reflective layer has a plurality of patterns that are arranged in a quasi-periodic manner.

12. The image sensor of claim 11,
wherein, in the anti-reflective layer, an average pitch of the plurality of patterns is greater than a critical dimension (CD) of the plurality of patterns.

13. The image sensor of claim 11,
wherein, in the anti-reflective layer, a density of the plurality of patterns is uniform over a plurality of regions of the anti-reflective layer.

14. The image sensor of claim 11,
wherein, in the anti-reflective layer, a density of the plurality of patterns is greater than 0 and less than 1.

15. The image sensor of claim 11,
wherein the anti-reflective layer comprises a base layer with a plurality of engraved patterns which correspond to the plurality of patterns,
wherein a material is disposed in the plurality of patterns, and
wherein the material disposed in the plurality of patterns includes air, a metal, a polymer, or oxide.

16. The image sensor of claim 15,
wherein a density of the plurality of patterns of the anti-reflective layer satisfies Equation (1):
$$\sqrt{{n}_{l 1} \times {n}_{l 2}} = ( 1 - A ) {n}_{1} + A {n}_{2} \qquad ( 1 )$$
where:
A denotes the density of the plurality of patterns,
n₁₁ denotes a refractive index of a component located on the anti-reflective layer,
n₁₂ denotes a refractive index of a component located beneath the anti-reflective layer,
n₁ is a refractive index of the base layer, and
n₂ is a refractive index of the material disposed inside the plurality of patterns.

17. The image sensor of claim 11,
wherein, in the anti-reflective layer, at least one pattern of the plurality of patterns overlaps the optical lens array, and
wherein the at least one pattern aperiodically overlaps the optical lens array.

18. An image sensor comprising:
a sensor substrate including a first pixel configured to sense light of a first wavelength and a second pixel configured to sense light of a second wavelength that is different from the first wavelength;
a spacer that is transparent and disposed on the sensor substrate;
a color filter array including a first color filter and a second color filter and disposed between the sensor substrate and the spacer, wherein the first color filter and the second color filter overlap the first pixel and the second pixel, respectively;
a first color separation lens array disposed on the spacer,
wherein the first color separation lens array includes:
a plurality of first nanoposts arranged to concentrate incident light on the first pixel and the second pixel, and
a first dielectric layer surrounding a side surface of each first nanosheet of the plurality of first nanoposts and including a dielectric material having a refractive index lower than a refractive index of a material of the plurality of first nanoposts;
a second color separation lens array disposed on the first color separation lens array,
wherein the second color separation lens array includes:
a plurality of second nanoposts arranged at a horizontal directional position that is different from a horizontal directional position of the plurality of first nanoposts, and
a second dielectric layer surrounding a side surface of each second nanopost of the plurality of second nanoposts and including a dielectric material having a refractive index lower than a material of the plurality of second nanoposts;
a first etch stopper disposed between the spacer and the first color separation lens array; and
an anti-reflective layer located at least one of:
on an upper surface of the second color separation lens array,
between the spacer and the color filter array, and
between the color filter array and the sensor substrate,
wherein the anti-reflective layer has a plurality of patterns that are arranged in a quasi-periodic manner.

19. The image sensor of claim 18,
wherein the anti-reflective layer comprises a base layer with a plurality of engraved patterns which correspond to the plurality of patterns,
wherein a material is disposed in the plurality of patterns, and
wherein the material disposed in the plurality of patterns includes air, a metal, a polymer, or oxide.

20. The image sensor of claim 19,
wherein a density of the plurality of patterns of the anti-reflective layer satisfies Equation (1):
$$\sqrt{{n}_{l 1} \times {n}_{l 2}} = ( 1 - A ) {n}_{1} + A {n}_{2} \qquad ( 1 )$$
where:
A denotes the density of the plurality of patterns,
n₁₁ denotes a refractive index of a component located on the anti-reflective layer,
n₁₂ denotes a refractive index of a component located beneath the anti-reflective layer,
n₁ is a refractive index of the base layer, and
n₂ is a refractive index of the material disposed inside the plurality of patterns.
